(19) United States
(12) Patent Application Publication
(10) Pub. No.: US 2011/0280270 A1
(43) Pub. Date: Nov. 17, 2011

(54) SEMICONDUCTOR LASER APPARATUS AND OPTICAL APPARATUS

(75) Inventor: Nobuhiko HAYASHI, Osaka-shi (JP)

(73) Assignee: SANYO ELECTRIC CO., LTD., Moriguchi-shi (JP)

(21) Appl. No.: 13/105,941

(22) Filed: May 12, 2011

(30) Foreign Application Priority Data
May 14, 2010 (JP) 2010-112231

(51) Int. Cl. H01S 5/026

(52) U.S. Cl. 372/50.1

(57) ABSTRACT

This semiconductor laser apparatus includes a semiconductor laser chip and a package sealing the semiconductor laser chip. The package has a concave base portion with an opening provided in an upper surface and one side surface and a sealing member covering the opening, and the sealing member is mounted on a bonded region of the base portion through a sealant.

### CROSS-REFERENCE TO RELATED APPLICATION

The priority application number JP2010-112231, Semiconductor Laser Apparatus and Optical Apparatus, May 14, 2010, Nobuhiko Hayashi, upon which this patent application is based is hereby incorporated by reference.

### BACKGROUND OF THE INVENTION

1. Field of the Invention

The present invention relates to a semiconductor laser apparatus and an optical apparatus, and more particularly, it relates to a semiconductor laser apparatus and an optical apparatus each comprising a base portion on which a semiconductor laser chip is placed and a sealing member mounted on the base portion.

2. Description of the Background Art

A semiconductor laser device has been widely applied as a light source for an optical disc system, an optical communication system or the like in general. For example, an infrared semiconductor laser device emitting a laser beam having a wavelength of about 780 nm has been put into practice as a light source for reading of a CD, and a red semiconductor laser device emitting a laser beam having a wavelength of about 650 nm has been put into practice as a light source for writing/reading of a DVD. A blue-violet semiconductor laser device emitting a laser beam having a wavelength of about 405 nm has been put into practice as a light source for a Blu-ray disc.

In order to attain such a light source apparatus, a semiconductor laser apparatus comprising a base portion on which a semiconductor laser chip is placed and a sealing member mounted on the base portion is known in general, as disclosed in each of Japanese Patent Laying-Open Nos. 9-205251 (1997) and 2009-152330, for example.

Japanese Patent Laying-Open No. 9-205251 (1997) discloses a plastic-molded apparatus of a semiconductor laser comprising a header formed with a flange surface and made of a resin product, a semiconductor laser chip mounted on a mounting plate fixed onto the header through a Si submount and a transparent cap of resin covering the periphery of the semiconductor laser chip. In this plastic-molded apparatus of a semiconductor laser, an edge of an opening of the transparent cap is bonded onto the flange surface of the header through an adhesive containing an epoxy resin-based material, whereby the semiconductor laser chip is hermetically sealed in a package surrounded by the header and the transparent cap.

Japanese Patent Laying-Open No. 2009-152330 discloses a semiconductor device mounted with a semiconductor laser chip in a metal package having an opening connecting from a front surface to an upper surface and a metal cap having a substantially L-shaped side cross section and sealing the opening of the package with two surfaces. In this semiconductor device described in Japanese Patent Laying-Open No. 2009-152330, the package and the cap are bonded to each other by resistance welding.

However, in the plastic-molded apparatus of a semiconductor laser disclosed in Japanese Patent Laying-Open No. 9-205251 (1997), the epoxy resin-based adhesive is employed to bond the header and the transparent cap to each other. This adhesive contains many volatile gas components such as organic gas especially before being hardened, and hence a large quantity of the volatile gas is conceivably generated by employing this adhesive. Especially when operating a blue-violet semiconductor laser device emitting a high-energy laser beam having a short lasing wavelength in a state where the package is filled with a large quantity of volatile gas, adherent substances may be formed on a laser emitting facet by exciting the volatile gas by the laser beam emitted from the laser emitting facet and degrading the same in the vicinity of the laser emitting facet. In this case, the adherent substances absorb the laser beam thereby causing temperature rise of the laser emitting facet, and hence the semiconductor laser chip is disadvantageously deteriorated.

In the semiconductor device disclosed in Japanese Patent Laying-Open No. 2009-152330, the package and the cap can be bonded to each other by resistance welding when the package and the cap are made of metal, but the package and the cap cannot be bonded to each other by welding when either the package or the cap is made of a material other than metal. When the laser chip is a blue-violet semiconductor laser chip, adherent substances may be conceivably formed on a laser emitting facet due to volatile gas volatilizing from the adhesive if the epoxy resin-based adhesive disclosed in the aforementioned Japanese Patent Laying-Open No. 9-205251 (1997) is employed to bond the package and the cap. Therefore, the adherent substances absorb lights of a laser beam thereby causing temperature rise of the laser emitting facet, and hence the semiconductor laser chip is disadvantageously deteriorated.

### SUMMARY OF THE INVENTION

In order to attain the aforementioned objects, a semiconductor laser apparatus according to a first aspect of the present invention comprises a semiconductor laser chip, and a package sealing the semiconductor laser chip, wherein the package has a concave base portion with an opening provided in an upper surface and one side surface and a sealing member covering the opening, and the sealing member is mounted on a bonded region of the base portion through a sealant.

In the semiconductor laser apparatus according to the first aspect of the present invention, as hereinabove described, the opening is covered with the sealing member through the sealant, and hence the concave base portion having the opening in two surfaces of the upper surface and the one side surface can be easily sealed with the sealing member. Thus, the semiconductor laser chip in the package can be inhibited from deterioration.

In the aforementioned semiconductor laser apparatus according to the first aspect, the sealant is preferably made of a material hardly generating a volatile component causing an adherent substance on a laser emitting facet of the semiconductor laser chip. A substance causing formation of the adherent substance on the laser emitting facet is volatile gas such as organic gas or siloxane. According to this structure, the aforementioned volatile component does not enter the package, and hence the adherent substance can be inhibited from being formed on the laser emitting facet. Thus, the semiconductor laser chip can be inhibited from deterioration. Especially in a semiconductor laser apparatus comprising a nitride-based semiconductor laser chip, the adherent substance resulting from the volatile gas is easily formed on a laser emitting facet of the laser chip, and hence it is effective to employ the sealant of the present invention.

In the aforementioned structure, the sealant is preferably made of an ethylene-polyvinyl alcohol copolymer. The ethylene-polyvinyl alcohol copolymer is a resin material with excellent gas barrier properties blocking outside air, and hence low molecular siloxane, volatile organic gas or the like existing outside the semiconductor laser apparatus (in the atmosphere) can be inhibited from penetrating into the sealant and entering the package. Further, the ethylene-polyvinyl alcohol copolymer hardly generates the aforementioned volatile component, and hence the adherent substance is inhibited from being formed on the laser emitting facet. Consequently, the semiconductor laser chip can be reliably inhibited from deterioration. The inventor has found as a result of a deep study that the aforementioned ethylene-polyvinyl alcohol copolymer is employed as the material hardly generating the volatile component forming the adherent substance on the laser emitting facet.

In the aforementioned structure in which the sealant is made of the material hardly generating the volatile component forming the adherent substance on the laser emitting facet of the semiconductor laser chip, the sealant is preferably made of fluorine-based resin. The fluorine-based resin hardly generates the aforementioned volatile component, and hence the adherent substance is inhibited from being formed on the laser emitting facet. Consequently, the semiconductor laser chip can be reliably inhibited from deterioration. The inventor has found as a result of a deep study that the aforementioned fluorine-based resin is employed as the material hardly generating the volatile component forming the adherent substance on the laser emitting facet.

In this case, the fluorine-based resin is preferably fluorine-based grease. The fluorine-based grease is in paste form, whereby even a small clearance can be easily filled up with the fluorine-based grease, and hence an internal portion of the package can be sealed with no clearance. Consequently, the semiconductor laser chip can be reliably inhibited from deterioration.

In the aforementioned semiconductor laser apparatus according to the first aspect, the sealing member preferably has a first portion covering the upper surface of the base portion and a second portion covering the one side surface of the base portion, and the first portion and the second portion of the sealing member are preferably integrally formed. According to this structure, the concave base portion having the opening in the two surfaces of the upper surface and the one side surface can be sealed with a single member, and hence a manufacturing process can be simplified as compared with a case where the aforementioned two surfaces are sealed with different members.

In the aforementioned structure having the first portion and the second portion of the sealing member integrally formed, the sealing member preferably has translucence. According to this structure, the sealing member can also serve as a “window member” through which light emitted from the semiconductor laser chip penetrates to the outside, and hence a structure of the package can be simplified.

In the aforementioned structure having the first portion and the second portion of the sealing member integrally formed, the package preferably further includes a window member through which light emitted from the semiconductor laser chip penetrates to an outside thereof, the sealing member preferably further has a hole penetrating through the second portion, and the window member is preferably mounted on the second portion through the sealant to seal the hole of the second portion. According to this structure, the “sealant” in the present invention is employed to bond the second portion and the window member to each other also when the window member is provided, and hence volatile gas such as organic gas or siloxane can be reliably inhibited from entering the package.

In this case, the window member is preferably bonded onto a surface of the second portion opposite to a surface mounted on the base portion through the sealant. According to this structure, a surface (on a side of sealed space in the package) of the sealing member mounted on the base portion can be rendered flat, and hence the sealing member can be easily mounted on the concave base portion.

In the aforementioned semiconductor laser apparatus according to the first aspect, the sealant is preferably provided with no clearance all over said bonded region. According to this structure, the sealed space in the package can be reliably isolated from the outside of the package by the sealant provided with no clearance. Thus, the semiconductor laser chip can be reliably inhibited from deterioration.

In the aforementioned semiconductor laser apparatus according to the first aspect, the sealing member is preferably fixed onto the base portion with fixing means. According to this structure, the sealing member can be reliably fixed onto the base portion with the fixing means other than the sealant. Thus, the sealing member can be easily inhibited from disengaging from the base portion due to a sudden vibration or impact.

In the aforementioned structure having the sealing member fixed with the fixing means, the fixing means preferably includes an adhesive, and the adhesive is preferably provided outside the bonded region. According to this structure, even when the adhesive generates volatile organic gas, the volatile organic gas can be easily inhibited from penetrating into the sealed space (the inside of the package).

In the aforementioned structure having the sealing member fixed with the fixing means, the fixing means preferably includes a first fitting portion formed on the sealing member and a second fitting portion formed on the base portion, and the sealing member is preferably fixed onto the base portion by fitting the first fitting portion of the sealing member into the second fitting portion of the base portion. According to this structure, the sealing member can be easily fixed onto the base portion.

In this case, the first fitting portion and the second fitting portion are preferably fitted into each other at a position separated from the bonded region. According to this structure, the sealant is inhibited from protruding to a fitting section of the first fitting portion and the second fitting portion when the sealing member is mounted on the base portion. Thus, the sealant does not intervene in the fitting section of the first fitting portion and the second fitting portion, and hence the first fitting portion and the second fitting portion can be reliably fitted into each other. Consequently, the sealing member can be reliably inhibited from disengaging from the base portion due to a sudden vibration or impact.

In the aforementioned semiconductor laser apparatus according to the first aspect, the base portion and the sealing member are preferably made of resin. According to this structure, even when the base portion and the sealing member both made of resin, being flexible and relatively soft are employed, the package can be reliably sealed with the sealant, as compared with metal members. Thus, the semiconductor laser apparatus further reduced in weight can be obtained as compared with a semiconductor laser apparatus constituted by metal members.

In the aforementioned semiconductor laser apparatus according to the first aspect, the sealing member is preferably made of any of metal foil, silicon resin having a gas barrier layer formed on a surface and thermoplastic fluorine resin having a gas barrier layer formed on a surface. In the present invention, the gas barrier layer means a layer made of a material having lower gas permeability than silicon resin and thermoplastic fluorine resin. According to this structure, the sealing member can be easily formed of a low-cost material having excellent workability other than resin when the sealing member is made of metal foil. Further, the gas barrier layer can inhibit low molecular siloxane, volatile organic gas or the like existing outside the semiconductor laser apparatus from penetrating into the resin of the sealing member and entering the package when the sealing member is made of resin such as silicon resin or thermoplastic fluorine resin.

In the aforementioned structure having the sealing member made of any of metal foil, silicon resin and thermoplastic fluorine resin, the sealing member is preferably made of Al metal foil, the sealant is preferably made of an ethylene-polyvinyl alcohol copolymer, and the sealant preferably extends to a surface of the sealing member bonded to the base portion other than the bonded region. According to this structure, the physical strength (rigidity) of the meal foil can be improved by the sealant provided on the sealing member, and hence the sealing member having a prescribed magnitude of rigidity can be easily made even when a low-cost Al metal foil is employed.

In the aforementioned structure having the sealing member made of any of metal foil, silicon resin and thermoplastic fluorine resin, the gas barrier layer is preferably formed on a surface of the sealing member bonded to the base portion, and the gas barrier layer is preferably in contact with the sealant. According to this structure, the bas barrier layer intervenes between the sealing member and the sealant in the bonded region of the sealing member and the base portion, and hence low molecular siloxane, volatile organic gas or the like existing outside the semiconductor laser apparatus can be further inhibited from entering the package. Consequently, the semiconductor laser chip can be further inhibited from deterioration.

In the aforementioned semiconductor laser apparatus according to the first aspect, the semiconductor laser chip is preferably a nitride-based semiconductor laser chip. In the nitride-based semiconductor laser device having a short lasing wavelength and requiring a higher output power, the adherent substance is easily formed on the laser emitting facet of the semiconductor laser chip, and hence the use of the aforementioned “sealant” in the present invention is highly effective in that the nitride-based semiconductor laser chip is inhibited from deterioration.

An optical apparatus according to a second aspect of the present invention comprises a semiconductor laser apparatus including a semiconductor laser chip and a package sealing the semiconductor laser chip, and an optical system controlling a beam emitted from the semiconductor laser apparatus, wherein the package has a concave base portion with an opening provided in an upper surface and one side surface and a sealing member covering the opening, and the sealing member is mounted on a bonded region of the base portion through a sealant.

In the optical apparatus according to the second aspect of the present invention, as hereinabove described, the opening is covered with the sealing member through the sealant, and hence the semiconductor laser apparatus in which the concave base portion having the opening in two surfaces of the upper surface and the one side surface is easily sealed with the sealing member can be obtained. Thus, the optical apparatus loaded with the semiconductor laser apparatus having the semiconductor laser chip inhibited from deterioration can be obtained.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is an exploded perspective view of a semiconductor laser apparatus according to a first embodiment of the present invention, in which a base portion and a sealing member are separated from each other;

FIG. 2 is a perspective view of the semiconductor laser apparatus according to the first embodiment of the present invention, in which the sealing member is mounted on the base portion;

FIG. 3 is a top plan view of the semiconductor laser apparatus according to the first embodiment of the present invention, from which the sealing member of is removed;

FIG. 4 is a longitudinal sectional view taken along the center line of the semiconductor laser apparatus according to the first embodiment of the present invention in a width direction;

FIG. 5 is a front elevational view in viewing the semiconductor laser apparatus according to the first embodiment of the present invention from a laser beam-emitting direction;

FIGS. 6 and 7 are top plan views for illustrating a manufacturing process of the semiconductor laser apparatus according to the first embodiment of the present invention;

FIG. 8 is an exploded perspective view of a semiconductor laser apparatus according to a second embodiment of the present invention, in which a base portion and a sealing member are separated from each other;

FIG. 9 is a longitudinal sectional view taken along the center line of the semiconductor laser apparatus according to the second embodiment of the present invention in a width direction;

FIGS. 10 to 12 are perspective views for illustrating a manufacturing process of the semiconductor laser apparatus according to the second embodiment of the present invention;

FIG. 13 is an exploded perspective view of a semiconductor laser apparatus according to a third embodiment of the present invention, in which a base portion and a sealing member are separated from each other;

FIG. 14 is a perspective view of a semiconductor laser apparatus according to a fourth embodiment of the present invention, in which a sealing member is mounted on a base portion;

FIGS. 15 and 16 are sectional views for illustrating a manufacturing process of the semiconductor laser apparatus according to the fourth embodiment of the present invention;

FIG. 17 is an exploded perspective view of a semiconductor laser apparatus according to a fifth embodiment of the present invention, in which a base portion and a sealing member are separated from each other;

FIG. 18 is a longitudinal sectional view taken along the center line of the semiconductor laser apparatus according to the fifth embodiment of the present invention in a width direction;

FIG. 19 is a sectional view in viewing the semiconductor laser apparatus according to the fifth embodiment of the present invention from a laser beam-emitting direction;

FIG. 20 is a top plan view of a three-wavelength semiconductor laser apparatus according to a sixth embodiment of the present invention, from which a sealing member is removed;

FIG. 21 is a front elevational view in viewing the three-wavelength semiconductor laser apparatus according to the sixth embodiment of the present invention from a laser beam-emitting direction;

FIG. 22 is a schematic diagram showing a structure of an optical pickup according to a seventh embodiment of the present invention;

FIG. 23 is a block diagram of an optical disc apparatus comprising an optical pickup according to an eighth embodiment of the present invention;

FIG. 24 is a front elevational view in viewing an RGB three-wavelength semiconductor laser apparatus according to a ninth embodiment of the present invention from a laser beam-emitting direction;

FIG. 25 is a schematic diagram of a projector comprising the RGB three-wavelength semiconductor laser apparatus according to the ninth embodiment of the present invention;

FIG. 26 is a schematic diagram of a projector according to a tenth embodiment of the present invention; and

FIG. 27 is a timing chart showing a state where a control portion transmits signals in a time-series manner in the projector according to the tenth embodiment of the present invention.

### DESCRIPTION OF THE PREFERRED EMBODIMENTS

Embodiments of the present invention are hereinafter described with reference to the drawings.

### First Embodiment

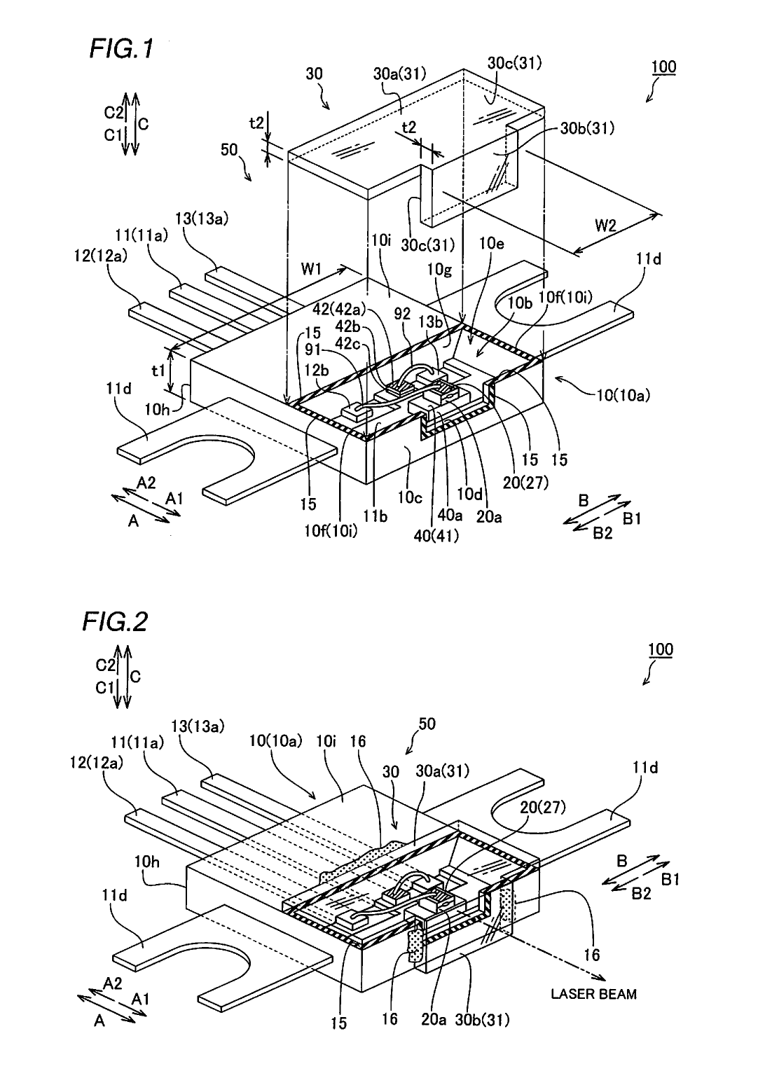

A structure of a semiconductor laser apparatus 100 according to a first embodiment of the present invention is described with reference to FIGS. 1 to 5. In FIG. 2, some reference numerals are omitted to show a semiconductor laser chip sealed in a package and the periphery thereof.

The semiconductor laser apparatus 100 according to the first embodiment of the present invention is constituted by a blue-violet semiconductor laser chip 20 having a lasing wavelength of about 405 nm and a package 50 sealing the blue-violet semiconductor laser chip 20, as shown in FIGS. 1 and 2. The package 50 has a base portion 10 mounted with the blue-violet semiconductor laser chip 20 and a sealing member 30 mounted on the base portion 10, covering the blue-violet semiconductor laser chip 20 from two directions, that is, from upper (a C2 side) and front (an A1 side) sides. The blue-violet semiconductor laser chip 20 is an example of the “semiconductor laser chip” in the present invention.

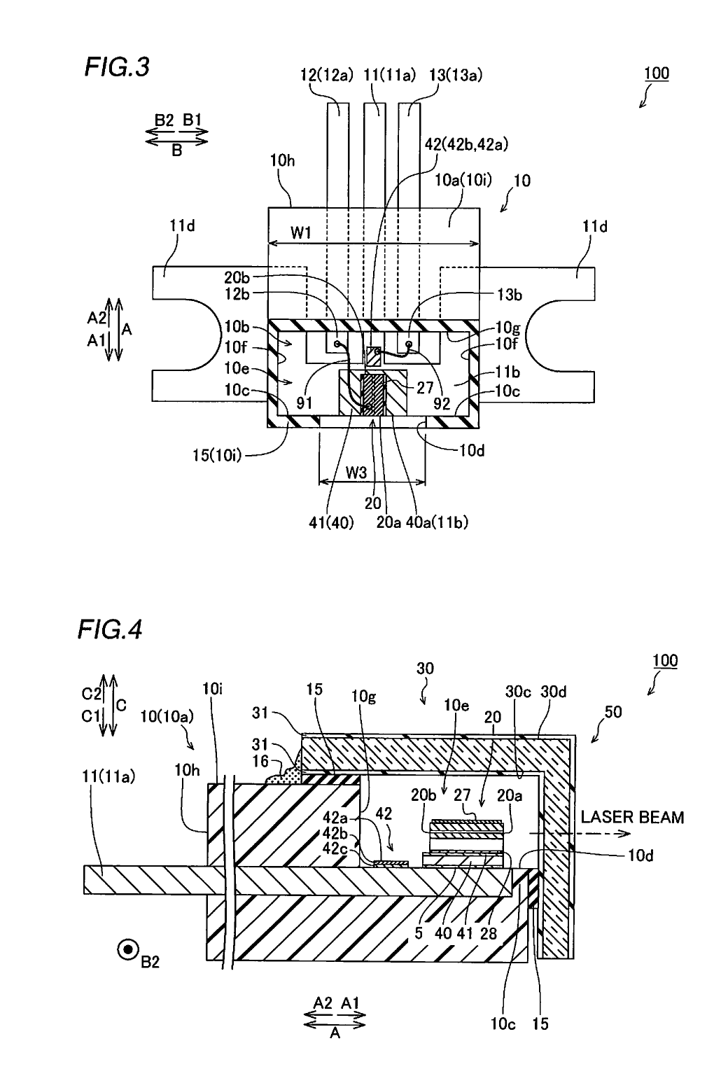

The base portion 10 has a tabular base body 10a with a thickness t1 (in a direction C) made of polyamide resin, as shown in FIG. 1. A recess portion 10b recessed by a depth about half the thickness t1 downward (to a C1 side) is formed in about a half region of the front portion (on the A1 side) of the tabular base body 10a. A front wall portion 10c of the base body 10a on the front side (on the A1 side) is provided with a substantially rectangular opening 10d having a width W3 (see FIG. 3) on the central portion in a width direction (direction B). Therefore, the recess portion 10b is arranged with a substantially rectangular opening 10e opening in an upper surface 10i and the opening 10d opening on the front side. The recess portion 10b is constituted by the front wall portion 10c, a pair of side wall portions 10f extending substantially parallel to each other backward (in a direction A2) from both side ends of the front wall portion 10c, an inner wall portion 10g connecting back ends (on an A2 side) of the side wall portions 10f and a bottom surface connecting the aforementioned front wall portion 10c, pair of side wall portions 10f and inner wall portion 10g on the lower portion. The front wall portion 10c is an example of the “one side surface” in the present invention.

As shown in FIGS. 1 and 3, in the base portion 10, lead terminals 11, 12 and 13 each constituted by a metal lead frame are so arranged as to pass through the base body 10a from the front side (A1 side) to the back side (A2 side) in a state of being isolated from each other. In plan view, the lead terminal 11 passes through a substantially central portion of the base body 10a (in the direction B) while the lead terminals 12 and 13 are arranged on the outer sides (a B2 side and a B1 side) of the lead terminal 11 in the width direction (direction B). Back end regions 11a, 12a and 13a of the lead terminals 11, 12 and 13, extending backward (in the direction A2) are exposed from a back wall portion 10h (see FIG. 3) of the base body 10a at the back (on the A2 side).

As shown in FIGS. 1 and 3, front end regions 11b, 12b and 13b of the lead terminals 11, 12 and 13 at the front (on the A1 side) are exposed from the inner wall portion 10g of the base body 10a, and the front end regions 11b to 13b are arranged on the bottom surface of the recess portion 10b. The front end region 11b of the lead terminal 11 widens in the direction B on the bottom surface of the recess portion 10b.

As shown in FIG. 3, the lead terminal 11 is integrally formed with a pair of heat radiation portions 11d connected to the front end region 11b. The pair of heat radiation portions 11d are arranged substantially symmetrically about the lead terminal 11 on both sides in the direction B. Each of the heat radiation portions 11d extends from the front end region 11b and passes through a side surface of the base body 10a in a direction B1 (direction B2) to be exposed. Therefore, heat generated by the blue-violet semiconductor laser chip 20 operating in the package 50 is transferred to a submount 40, the front end region 11b and the heat radiation portions 11d on both sides to be radiated to the outside of the semiconductor laser apparatus 100.

The sealing member 30 is made of translucent silicon resin. The sealing member 30 integrally has a tabular ceiling surface portion 30a with a thickness t2 (in the direction C) and a width W1 (in the direction B) and a tabular front surface portion 30b with a thickness t2 and a width W2 (W2≦W1) connected to an end of the ceiling surface portion 30a on one side (the A1 side) and extending downward (in a direction C1), as shown in FIG. 1. The ceiling surface portion 30a and the front surface portion 30b are integrally formed in a state of being substantially orthogonal to each other, whereby a side cross section of the sealing member 30 in a direction A is substantially L-shaped. The width W2 of the front surface portion 30b is larger than an opening length W3 (see FIG. 3) of the opening 10d of the base portion 10 in the direction B. The ceiling surface portion 30a and the front surface portion 30b are examples of the “first portion” and the “second portion” in the present invention, respectively.

As shown in FIGS. 1 to 5, a sealant 15 continuously covering a peripheral region (a region near the inner wall portion 10g and respective upper surfaces of the pair of side wall portions 10f and the front wall portion 10c) of the opening 10e in the upper surface 10i of the base body 10a and a peripheral region of the opening 10d in the front surface (an outer surface (on the A1 side) of the front wall portion 10c) is applied with a prescribed thickness so as to surround the periphery of the openings 10e and 10d. The sealing member 30 is mounted on the base portion 10 in a state where the vicinity of an outer edge of an inner surface 30c of the ceiling surface portion 30a and the front surface portion 30b is attached to the sealant 15. In other words, the opening 10e of the base body 10a is covered with the ceiling surface portion 30a, and the opening 10d of the base body 10a is covered with the front surface portion 30b. Thus, the openings 10d and 10e are completely closed by the sealing member 30, and the blue-violet semiconductor laser chip 20 is sealed with the package 50.

Fluorine-based grease made of a paste mixture prepared by mixing particles of polytetrafluoroethylene (CF₂)ₙ) serving as a thickening agent into perfluoropolyether, which is fluorine-based oil, is employed as the sealant 15. Perfluoropolyether includes a simple substance or combination of substances shown in the following chemical formulas. In other words, perfluoropolyether includes a simple substance or combination of Rf(OCF₂CF₂)ₙF, Rf(OCF₂CF₂CF₂)ₙF, Rf(OCF(CF₃)CF₂)ₙF (Rf indicates C₃F₅ or C₃F₇), or Rf(OCF₂CF₂)ₙF (Rf indicates C₂F₅ or C₃F₇). Thus, a material not generating a volatile component or the like, or a material hardly generating a volatile component or the like is employed as the sealant 15. Thus, in the semiconductor laser apparatus 100, adherent substances or the like resulting from the volatile component are not generated or hardly generated on a light-emitting facet 20a in the package 50.

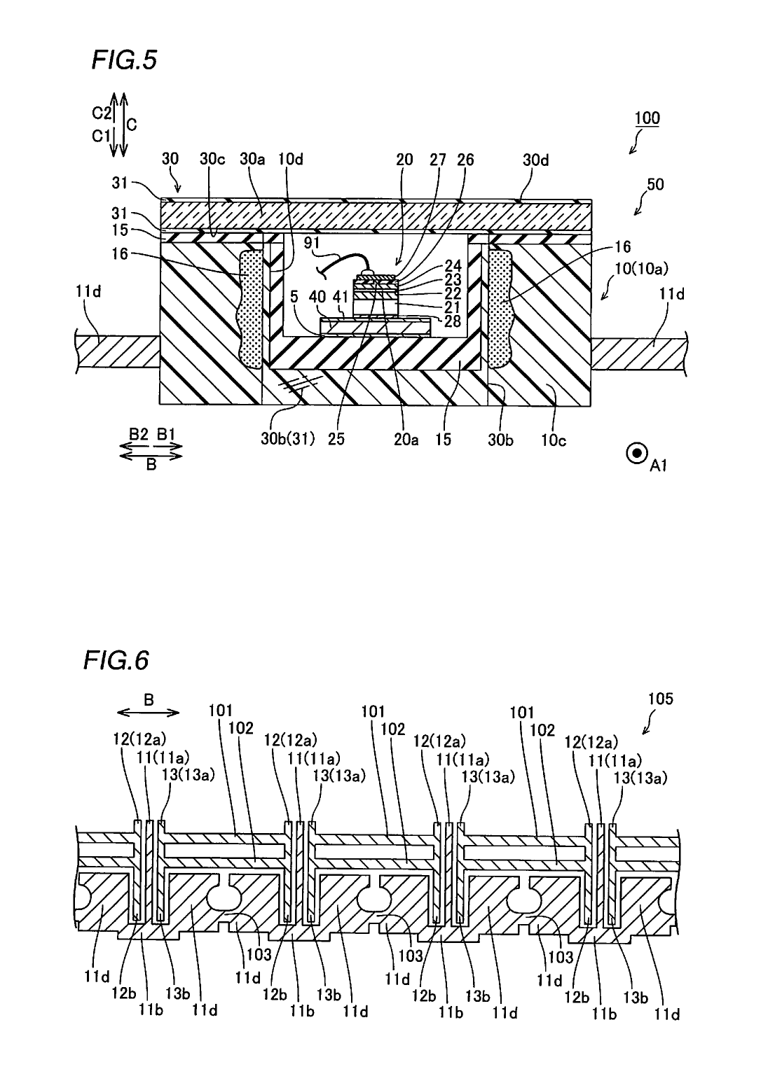

As shown in FIGS. 4 and 5, gas barrier layers 31 each having a thickness of about 0.1 μm, made of SiO₂ are continuously formed on the inner surface 30c and an outer surface 30d of the sealing member 30.

As shown in FIG. 2, the sealing member 30 is further fixed with epoxy resin adhesives 16 in a state where the sealing member 30 is mounted on the base portion 10. More specifically, the adhesives 16 are provided in the vicinity of a back facet (on the A2 side) of the ceiling surface portion 30a of the sealing member 30 and the vicinities of lateral facets (on the B1 and B2 sides) of the front surface portion 30b. The adhesives 16 are formed from an outer surface of the base portion 10 to an outer surface of the sealing member 30 at each part and provided outside the sealant 15 (outside the recess portion 10b). Thus, the sealant 15 prevents volatile organic gas generated by the adhesives 16 from penetrating into the package 50. The adhesive 16 is an example of the “fixing means” in the present invention.

The blue-violet semiconductor laser chip 20 is mounted on a substantially central portion of an upper surface of the front end region 11b of the lead terminal 11 through the submount 40. This blue-violet semiconductor laser chip 20 has a cavity length (in the direction A) of at least about 250 μm and not more than about 400 μm and a chip width (in the direction B) of at least about 100 μm and not more than about 200 μm. The blue-violet semiconductor laser chip 20 has a thickness of about 100 μm.

As shown in FIG. 5, the blue-violet semiconductor laser chip 20 is formed with an n-type cladding layer 22 made of Si-doped n-type AlGaN on an upper surface of an n-type GaN substrate 21. An active layer 23 having an MQW structure formed by alternately staking quantum well layers made of InGaN having a higher In composition and barrier layers made of GaN is formed on an upper surface of the n-type cladding layer 22. A p-type cladding layer 24 made of Mg-doped p-type AlGaN is formed on an upper surface of the active layer 23.

The p-type cladding layer 24 is formed with a ridge (projecting portion) 25 having a width of about 1.5 μm extending along a direction (the direction A in FIG. 3) perpendicular to the plane of FIG. 5. A current blocking layer 26 made of SiO₂ is formed on an upper surface of the p-type cladding layer 24 other than the ridge 25 and both side surfaces of the ridge 25. A p-side electrode 27 made of Au or the like is formed on upper surfaces of the ridge 25 of the p-type cladding layer 24 and the current blocking layer 26.

An n-side electrode 28 prepared by stacking an Al layer, a Pt layer and an Au layer successively from a side closer to the n-type GaN substrate 21 is formed on a substantially entire region of a lower surface of the n-type GaN substrate 21. A dielectric multilayer film of low reflectance is formed on the light-emitting facet 20a (see FIG. 3) of the blue-violet semiconductor laser chip 20. A dielectric multilayer film of high reflectance is formed on a light-reflecting facet 20b (see FIG. 3). The aforementioned light-emitting facet 20a and light-reflecting facet 20b are distinguished from each other through the large-small relation between the strength levels of laser beams emitted from a pair of cavity facets formed on the blue-violet semiconductor laser chip 20. In other words, the light-emitting facet 20a has relatively larger light strength of the laser beam emitted from the facet, and the light-reflecting facet 20b has relatively smaller light strength of the laser beam. The light-reflecting facet 20b is an example of the “laser emitting facet” in the present invention.

The aforementioned n-side electrode 28 of the blue-violet semiconductor laser chip 20 and a pad electrode 41 formed on an upper surface of the submount 40 are bonded to each other through a conductive adhesive layer (not shown). Thus, the blue-violet semiconductor laser chip 20 is bonded onto the submount 40 in a junction-up system (see FIG. 5). The submount 40 is bonded onto a surface (upper surface) of the front end region 11b of the lead terminal 11 through a conductive adhesive layer 5 having a lower surface of Au—Sn solder. At this time, the light-emitting facet 20a of the blue-violet semiconductor laser chip 20 is aligned on the same plane as a facet 40a of the submount 40 on the A1 side, a front surface of the front end region 11b of the lead terminal 11 and the front wall portion 10c of the recess portion 10b of the base portion 10 (see FIG. 3). As shown in FIG. 1, a first end of a metal wire 91 made of Au or the like is bonded to the p-side electrode 27, and a second end of the metal wire 91 is connected to the front end region 12b of the lead terminal 12.

A tabular monitor PD (photodiode) 42 is arranged at the rear (on the A2 side) of the submount 40. The monitor PD 42 has a p-type region 42b formed on a side (C2 side) closer to an upper surface 42a serving as a photoreceiving surface and an n-type region 42c formed on a side (C1 side) closer to the lower surface. The n-type region 42c on the side closer to the lower surface is bonded onto an upper surface of the lead terminal 11.

A first end of a metal wire 92 made of Au or the like is bonded to the upper surface 42a of the monitor PD 42, and a second end of the metal wire 92 is connected to the front end region 13b of the lead terminal 13. The semiconductor laser apparatus 100 according to the first embodiment is constituted in the aforementioned manner.

A manufacturing process of the semiconductor laser apparatus 100 according to the first embodiment is now described with reference to FIGS. 1 to 7.

As shown in FIG. 6, a metal plate made of a strip-shaped thin plate of iron, copper or the like is etched, thereby forming a lead frame 105 in which the lead terminals 11 each having the heat radiation portions 11d formed integrally with the front end region 11b and the lead terminals 12 and 13 arranged on both sides of the respective lead terminals 11 are repeatedly patterned laterally (in the direction B). At this time, each of the lead terminals 12 and 13 is patterned in a state of being coupled by coupling portions 101 and 102. Each of the heat radiation portions 11d is patterned in a state of being coupled by a coupling portion 103 extending laterally.

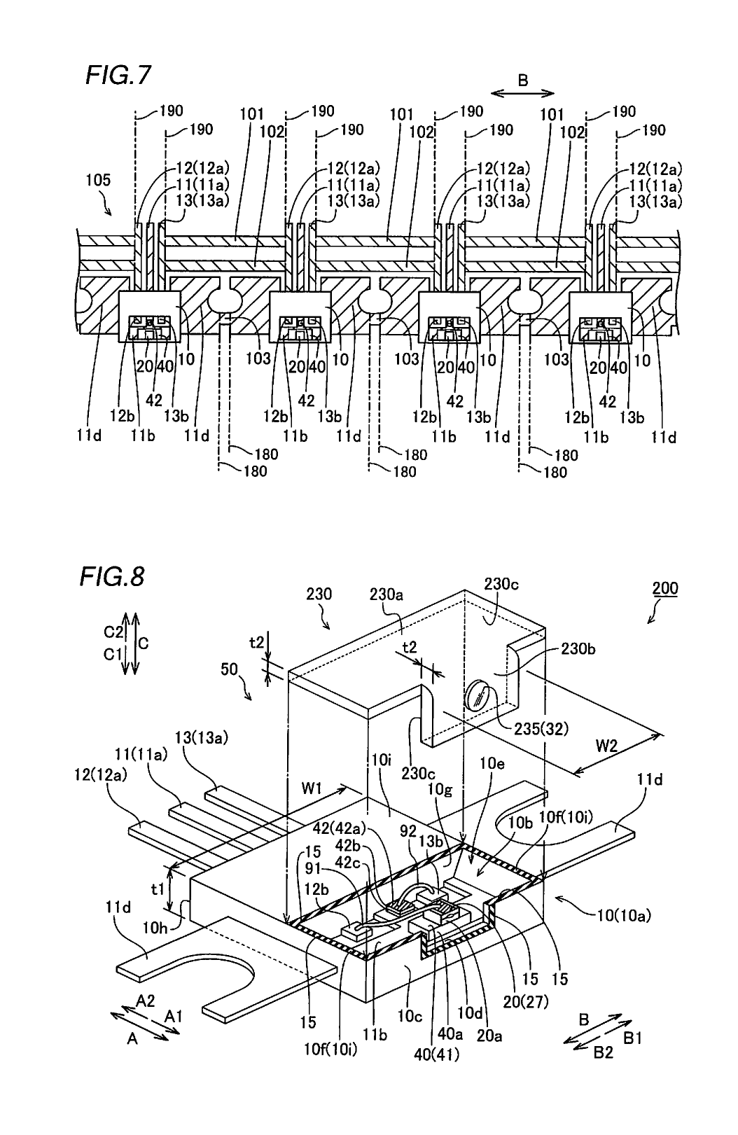

Thereafter, the base portion 10 (see FIG. 1) having the base body 10a through which a set of the lead terminals 11 to 13 passes and the recess portion 10b with a bottom surface on which the front end regions 11b to 13b of the respective terminals are exposed is molded in the lead frame 105 by a resin molding apparatus, as shown in FIG. 7. At this time, the base body 10a is so molded that the front end regions 11b to 13b of the lead terminals 11 to 13 are arranged in the recess portion 10b.

On the other hand, pre-hardened silicon resin prepared by mixing silicon resin and a hardening agent in a ratio of about 10:1 is poured into a mold (not shown) having a prescribed shape. Then, the silicon resin is heated for about 30 minutes under a temperature condition of about 150° C. to be hardened. Thus, the ceiling surface portion 30a and the front surface portion 30b (see FIG. 1) of the sealing member 30 are molded.

Thereafter, the sealing member 30 is removed from the mold and heated for about 2 days under a temperature condition of about 240° C. in an oven having a reduced pressure environment created by an oil-free pump, thereby removing low molecular siloxane contained in the silicon resin.

Thereafter, the gas barrier layers 31 (see FIG. 5) made of SiO₂ are formed on respective surfaces (the inner surface 30c and the outer surface 30d) of the ceiling surface portion 30a and the front surface portion 30b of the sealing member 30 by vacuum evaporation. The sealing member 30 is formed in the aforementioned manner.

The blue-violet semiconductor laser chip 20, the monitor PD 42 and the submount 40 are prepared through prescribed manufacturing processes. Then, a chip of the blue-violet semiconductor laser chip 20 is bonded to the pad electrode 41 formed on one surface of the submount 40 through the conductive adhesive layer (not shown). At this time, the n-side electrode 28 of the blue-violet semiconductor laser chip 20 is bonded to the pad electrode 41.

Thereafter, the submount 40 is bonded onto the substantially central portion (in a lateral direction) of the upper surface of the front end region 11b (see FIG. 3) through the conductive adhesive layer 5 (see FIG. 5), as shown in FIG. 7. At this time, a lower surface of the submount 40 to which the blue-violet semiconductor laser chip 20 is not bonded is bonded onto the upper surface of the front end region 11b. Then, the n-type region 42c of the monitor PD 42 is bonded onto a region at the rear of the submount 40 and between the front end region 11b of the lead terminal 11 and the front wall portion 10c through a conductive adhesive layer (not shown). At this time, the n-type region 42c of the monitor PD 42 is bonded to the lead terminal 11.

Thereafter, the p-side electrode 27 of the blue-violet semiconductor laser chip 20 and the front end region 12b of the lead terminal 12 are connected with each other through the metal wire 91, as shown in FIG. 1. The p-type region 42b of the monitor PD 42 and the front end region 13b of the lead terminal 13 are connected with each other through the metal wire 92. In FIG. 7, illustrations of the metal wires 91 and 92 are omitted.

Thereafter, the lead frame 105 is cut along division lines 180 and 190, thereby cutting and removing the coupling portions 101, 102 and 103, as shown in FIG. 7.

Thereafter, the sealant 15 continuously covering the peripheral region (the region near the inner wall portion 10g and the respective upper surfaces of the pair of side wall portions 10f and the front wall portion 10c) of the opening 10e in the upper surface 10i of the base body 10a and the peripheral region of the opening 10d in the front surface (the outer surface (on the A1 side) of the front wall portion 10c) is so applied as to surround the periphery of the openings 10e and 10d of the base portion 10, as shown in FIG. 1. In this state, the sealing member 30 is mounted on the base portion 10 while attaching the vicinity of the outer edge of the inner surface 30c of the sealing member 30 to the sealant 15. Finally, the adhesives 16 are bonded onto outer surfaces of bonded portions of the sealing member 30 and the base portion 10 thereby fixing the sealing member 30 and the base portion 10 onto each other. The semiconductor laser apparatus 100 (see FIG. 2) is formed in the aforementioned manner.

As hereinabove described, the openings 10e and 10d are covered with the sealing member 30 through the sealant 15, and hence the concave base portion 10 having the openings in two surfaces of the upper surface 10i and the front wall portion 10c can be easily sealed with the sealing member 30. Therefore, the blue-violet semiconductor laser chip 20 in the package 50 can be inhibited from deterioration. Further, the sealing member 30 is mounted on the base portion 10 through the sealant 15, whereby the semiconductor laser apparatus 100 can be easily manufactured with existing manufacturing equipments without increasing the manufacturing cost.

The fluorine-based grease hardly generating a volatile component causing adherent substances on the light-emitting facet 20a is employed as the sealant 15, whereby volatile gas such as organic gas or siloxane causing the adherent substances on the light-emitting facet 20a hardly enters the package 50, and hence the adherent substances are inhibited from being formed on the light-emitting facet 20a. Thus, the blue-violet semiconductor laser chip 20 sealed with the base portion 10 and the sealing member 30 can be inhibited from deterioration. The fluorine-based grease is in paste form, whereby even a small clearance can be easily filled up with the fluorine-based grease, and hence an internal portion of the package 50 can be sealed with no clearance. Thus, the blue-violet semiconductor laser chip 20 can be reliably inhibited from deterioration. It is effective to employ the sealant 15 made of the fluorine-based grease especially in the semiconductor laser apparatus 100 comprising the blue-violet semiconductor laser chip 20 easily deteriorating due to the adherent substances on the laser emitting facet (light-emitting facet 20a).

In order to confirm usefulness of employing the fluorine-based grease as the sealant 15, the following experiment was performed. First, the blue-violet semiconductor laser chip 20 was mounted on a metal stem (base portion) having a diameter (outer diameter) of 5.6 mm, and in a state where the fluorine-based grease of about 3 mg is applied to an inner surface of a metal cap portion (with a glass window), the stem was sealed with the cap portion. As the fluorine-based grease, each of “HP-300” manufactured by Dow Corning Toray Co., Ltd. and “Super Z-300” manufactured by ULVAC, Inc. was used. Then, an operation test was performed by emitting a laser beam adjusted to 10 mW output power by APC (Automatic Power Control) from the blue-violet semiconductor laser chip 20 for 350 hours under a condition of 70° C. Consequently, an operating current of a semiconductor laser apparatus to which each of the two types of fluorine-based grease is applied did not remarkably change even after 350 hours. As a comparative example, an operation test was performed with a semiconductor laser apparatus having the semiconductor laser chip sealed by applying silicon-based grease to the inner surface of the cap portion. As the silicon-based grease, each of “FS High Vacuum Grease” and “HIGH VACUUM GREASE” manufactured by Dow Corning Toray Co., Ltd. was used. In the case of the comparative example, an operating current value of the semiconductor laser apparatus was increased to 1.5 times an initial value after 20 to 50 hours of operation of the laser device. From these results, the fluorine-based grease employed as the sealant 15 is a material hardly generating the volatile component forming the adherent substances on the laser emitting facet, and it has been confirmed that the fluorine-based grease is useful to inhibit formation of the adherent substances or the like on the light-emitting facet 20a.

In order to confirm usefulness of employing the silicon resin as the sealing member 30, the following experiment was performed. First, the sealing member 30 was made of silicon resin (KE-106 manufactured by Shin-Etsu Chemical Co., Ltd.) with a thickness of 1 mm including plate-like polydimethylsiloxane and arranged at a distance of 1 mm from the light-emitting facet 20a. Next, a laser beam adjusted to 10 mW output power by APC (Automatic Power Control) was emitted from the blue-violet semiconductor laser chip 20 to the aforementioned light transmission portion 35 for 1000 hours under a condition of 70° C. Consequently, it has been confirmed that there is no change in transmittance of the sealing member 30. When a laser beam was emitted to a light transmission portion made of PMMA (transparent acrylic resin) with a thickness of 1 mm under the same condition as a comparative example, a region to which the laser beam was emitted became opaque due to deterioration and the transmittance was rapidly reduced. From these results, usefulness of employing the silicon resin as the sealing member 30 has been confirmed.

The ceiling surface portion 30a covering the upper surface 10i of the base portion 10 and the front surface portion 30b covering the front wall portion 10c of the base portion 10 are integrally formed on the sealing member 30. Thus, the concave base portion 10 having the openings in the two surfaces of the upper surface 10i and the front wall portion 10c can be sealed with the single sealing member 30, and hence the manufacturing process of the semiconductor laser apparatus 100 can be simplified, as compared with a case where the aforementioned two surfaces are sealed with separate sealing members.

The sealing member 30 has translucence, whereby the sealing member 30 can also serve as a window member through which light emitted from the blue-violet semiconductor laser chip 20 penetrates to the outside, and hence a structure of the package 50 can be simplified.

The sealant 15 is provided with no clearance along the peripheral region of a bonded region of the base portion 10 and the sealing member 30 (the peripheral region (the region near the inner wall portion 10g and the respective upper surfaces of the pair of side wall portions 10f and the front wall portion 10c) of the opening 10e and the peripheral region of the opening 10d in the front surface (the outer surface of the front wall portion 10c). Thus, sealed space in the package 50 can be reliably isolated from the outside of the package 50 by the sealant 15 provided with no clearance. Thus, the blue-violet semiconductor laser chip 20 can be reliably inhibited from deterioration.

The sealing member 30 is fixed onto the base portion 10 with the adhesives 16 in addition to the sealant 15. Thus, the sealing member 30 can be reliably fixed onto the base portion 10, and hence the sealing member 30 can be easily inhibited from disengaging from the base portion 10 due to a sudden vibration or impact.

The adhesives 16 are provided outside a region where the base portion 10 and the sealing member 30 are bonded to each other through the sealant 15. Thus, even when the adhesives 16 generate volatile organic gas, the volatile organic gas can be easily inhibited from penetrating into the sealed space (the inside of the package 50).

The base portion 10 and the sealing member 30 are made of resin. Even when the base portion 10 and the sealing member 30 both made of resin, being flexible and relatively soft are employed, the package 50 can be reliably sealed with the sealant 15, as compared with metal members. Thus, the semiconductor laser apparatus 100 further reduced in weight can be obtained as compared with a semiconductor laser apparatus constituted by metal members.

The silicon resin having the gas barrier layers 31 formed on the inner surface 30c and the outer surface 30d is employed as the sealing member 30. The silicon resin constituting the sealing member 30 has high gas permeability due to an amorphous structure, and hence there is a risk that low molecular siloxane or volatile organic gas existing outside the semiconductor laser apparatus 100 (in the atmosphere) penetrates into the silicon resin and enters the package 50 in which the blue-violet semiconductor laser chip 20 is sealed. Therefore, the gas barrier layers 31 are formed on the surfaces of the sealing member 30, whereby low molecular siloxane, volatile organic gas or the like existing outside the semiconductor laser apparatus 100 can be inhibited from penetrating into the silicon resin of the sealing member 30 and entering the package 50. The bas barrier layers 31 each may have a thickness of several 10 nm.

The gas barrier layer 31 is formed on the inner surface 30c of the sealing member 30 bonded to the base portion 10 through the sealant 15 and in contact with the sealant 15. Thus, the bas barrier layer 31 intervenes between the sealing member 30 and the sealant 15 in the bonded region of the sealing member 30 and the base portion 10, and hence low molecular siloxane, volatile organic gas or the like existing outside the semiconductor laser apparatus 100 can be further inhibited from entering the package 50. Consequently, the blue-violet semiconductor laser chip 20 can be further inhibited from deterioration.

The blue-violet semiconductor laser chip 20 is sealed in the package 50. In a nitride-based semiconductor laser device having a short lasing wavelength and requiring a higher output, adherent substances are easily formed on a laser emitting facet of the semiconductor laser chip, and hence the use of the sealant 15 is highly effective in that the blue-violet semiconductor laser chip 20 is inhibited from deterioration.

### Second Embodiment

A semiconductor laser apparatus 200 according to a second embodiment of the present invention is now described. In this semiconductor laser apparatus 200, as shown in FIG. 8, a sealing member 230 having a light transmission portion 235 formed on the front surface (A1 side) is made of aluminum foil, dissimilarly to the first embodiment. In the figures, a structure similar to that of the semiconductor laser apparatus 100 according to the first embodiment is denoted by the same reference numerals. The aluminum foil is an example of the “metal foil” in the present invention.

In the semiconductor laser apparatus 200, the sealing member 230 is formed using aluminum foil having a thickness t2 of about 50 μm.

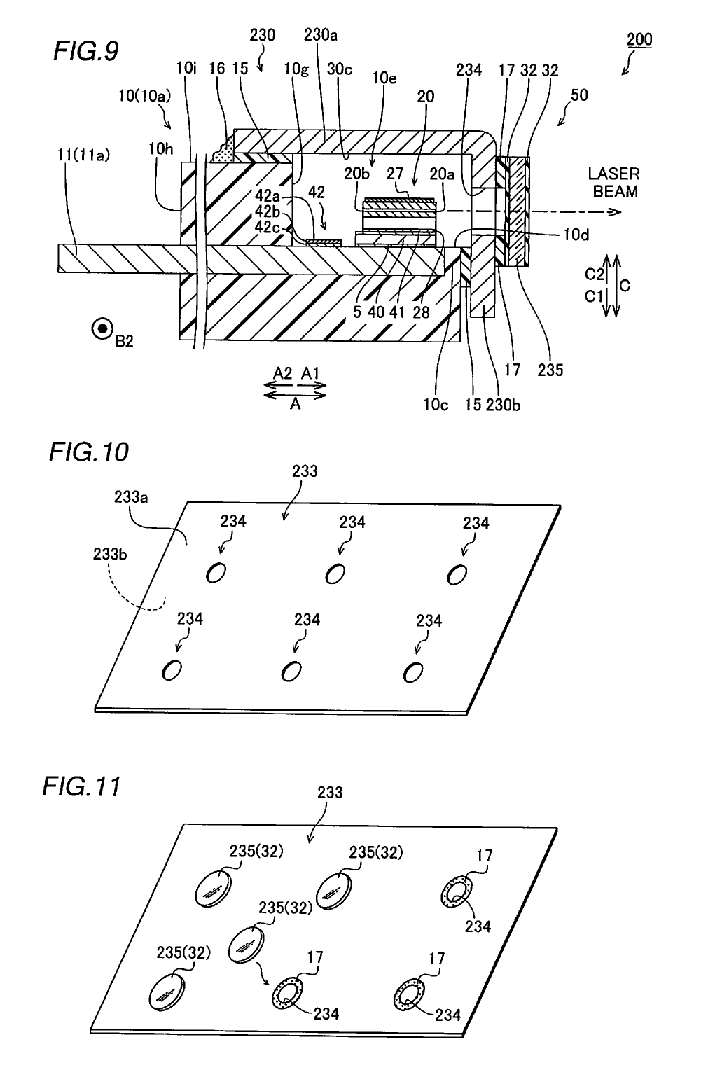

As shown in FIG. 9, a hole 234 penetrating through the sealing member 230 in a thickness direction is provided in a substantially central portion of a front surface portion 230b of the sealing member 230. The light transmission portion 235 having translucence, made of silicon resin is provided to cover the hole 234 from the outside (A1 side) of the front surface portion 230b. Dielectric films 32 made of Al₂O₃ are formed on surfaces (on the A1 side and an A2 side) of the light transmission portion 235. The dielectric films 32 each serve as an antireflection layer in addition to a gas barrier layer. The light transmission portion 235 is bonded onto the front surface portion 230b through a sealant 17 with a thickness of about 0.1 mm applied around the hole 234.

Eval (registered trademark) which is a resin (EVOH resin) including an ethylene-polyvinyl alcohol copolymer is employed as the sealant 17. The EVOH resin is a material having excellent gas barrier properties and mainly employed in a food wrapper and so on as a multilayered film. Therefore, the hole 234 of the sealing member 230 is completely closed by the light transmission portion 235 mounted through the sealant 17. The remaining structure of the semiconductor laser apparatus 200 is similar to that of the semiconductor laser apparatus 100 according to the first embodiment.

A manufacturing process of the semiconductor laser apparatus 200 is now described. As shown in FIG. 10, a plurality of the holes 234 are formed at prescribed intervals in prescribed regions of aluminum foil 233 having a thickness of about 50 μm. Thereafter, the sealant 17 is applied in an annular shape around each of the holes 234 on an upper surface 233a of the aluminum foil 233, as shown in FIG. 11.

At this time, the sealant 17 made of Eval (Eval F104B manufactured by Kuraray Co., Ltd.) is applied with a thickness of about 0.2 mm onto the upper surface 233a of the aluminum foil 233 heated to about 220° C. In a state where the sealant 17 is melted by heat, the dielectric films 32 are formed while the light transmission portion 235 formed in a substantially disc shape is press-bonded to cover the hole 234. Thereafter, the aluminum foil 233 is cooled thereby bonding the light transmission portion 235 onto the aluminum foil 233 through the sealant 17 (see FIG. 11).

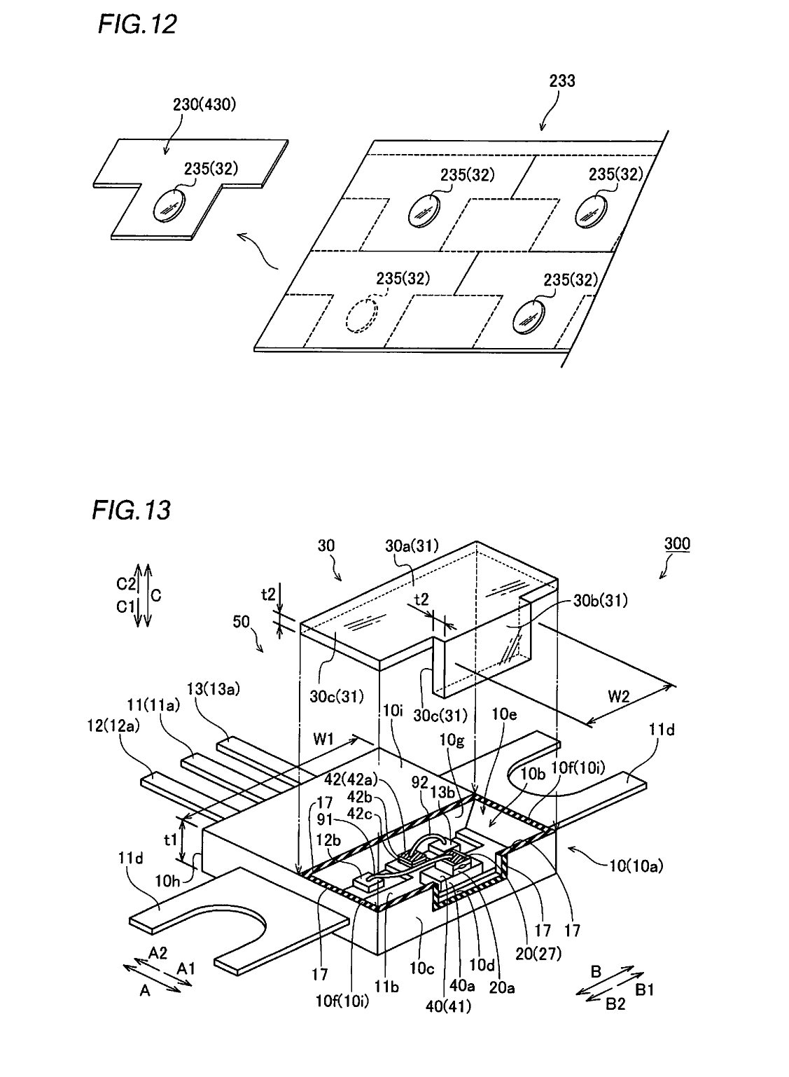

Thereafter, the aluminum foil 233 is cut in a shape of the sealing member 230 developed on a plane surface, as shown in FIG. 12. Then, the front surface portion 230b is bent in a direction perpendicular to a ceiling surface portion 230a such that the light transmission portion 235 is located outside. Thus, the sealing member 230 is formed in a shape shown in FIG. 8.

Thereafter, the sealing member 230 is mounted on the base portion 10 in place of a step of mounting the sealing member 30 on the base portion 10 in the manufacturing process of the first embodiment. The remaining steps are similar to those of the manufacturing process according to the first embodiment. The semiconductor laser apparatus 200 (see FIG. 9) is formed in the aforementioned manner.

According to the second embodiment, as hereinabove described, the sealing member 230 is made of the aluminum foil 233. Thus, the sealing member 230 can be easily formed of a low-cost material having excellent workability other than resin.

The light transmission portion 235 is so mounted on the front surface portion 230b through the sealant 17 as to seal the hole 234 of the front surface portion 230b. Thus, even when the light transmission portion 235 is provided, the sealant 17 is employed to bond the front surface portion 230b and the light transmission portion 235 to each other, and hence volatile gas such as organic gas or siloxane can be reliably inhibited from entering the package 50.

The light transmission portion 235 is mounted on the sealing member 230 (front surface portion 230b) through the sealant 17. In other words, the light transmission portion 235 and the sealing member 230 are bonded to each other with the sealant 17 without employing an adhesive such as an acrylic resin adhesive or an epoxy resin adhesive, and hence the blue-violet semiconductor laser chip 20 sealed in the package 50 is not exposed to organic gas generated by the aforementioned adhesive. Therefore, the blue-violet semiconductor laser chip 20 can be effectively inhibited from deterioration. Further, a surface (on a side of sealed space in the package 50) of the sealing member 230 mounted on the base portion 10 can be rendered flat, and hence the sealing member 230 can be easily mounted on the concave base portion 10.

In order to confirm usefulness of employing the EVOH resin (Eval) as the sealant 17, the following experiment was performed. First, the blue-violet semiconductor laser chip 20 was mounted on a metal stem (base portion) having a diameter (outer diameter) of 9 mm, and in a state where a pellet of Eval (Eval F104B manufactured by Kuraray Co., Ltd.) cut to weigh about 5 mg was put on an inner surface of a metal cap portion (with a glass window), the stem was sealed with the cap portion. Then, an operation test was performed by emitting a laser beam adjusted to 10 mW output power by APC from the blue-violet semiconductor laser chip 20 for 250 hours under a condition of 70° C. Consequently, an operating current of a semiconductor laser apparatus did not remarkably change even after 250 hours. As a comparative example, an operation test was performed in a semiconductor laser apparatus having the semiconductor laser chip sealed without putting the Eval on the inner surface of the cap portion. The operating current was not remarkably different from that in the comparative example after 250 hours. From these results, it has been confirmed that the Eval hardly generates organic gas, and usefulness of employing the EVOH resin as the sealant 17 has been confirmed.

### Third Embodiment

A third embodiment is described with reference to FIG. 13. A semiconductor laser apparatus 300 according to this third embodiment is similar to the semiconductor laser apparatus 100 according to the first embodiment except that the sealant 17 (Eval F104B manufactured by Kuraray Co., Ltd.) employed in the second embodiment is employed in place of the sealant 15 employed in the first embodiment. In the figure, a structure similar to that of the semiconductor laser apparatus 100 according to the first embodiment is denoted by the same reference numerals.

In a manufacturing process of the semiconductor laser apparatus 300, a sealing member 30 is mounted on a base portion through the following step in place of a step of mounting the sealing member 30 on the base portion 10 in the manufacturing process of the semiconductor laser apparatus 100. In other words, a sealant 17 (see FIG. 13) is applied onto peripheral regions of openings 10d and 10e in a state where the base portion 10 is heated to about 220° C. The sealing member 30 is press-bonded to the base portion 10 in a state where the sealant 17 is melted by heat. Thereafter, the base portion 10 is cooled thereby bonding the sealing member 30 to the base portion 10. The remaining steps are similar to those of the manufacturing process of the first embodiment. The semiconductor laser apparatus 300 is formed in the aforementioned manner. The effects of the third embodiment are similar to those of the first embodiment.

### Fourth Embodiment

A fourth embodiment is now described. A semiconductor laser apparatus 400 according to this fourth embodiment is similar to the semiconductor laser apparatus 200 according to the second embodiment except that a sealing member 430 is mounted on a base portion 10 with a sealant 17. In the figures, a structure similar to that of the semiconductor laser apparatus 200 according to the second embodiment is denoted by the same reference numerals.

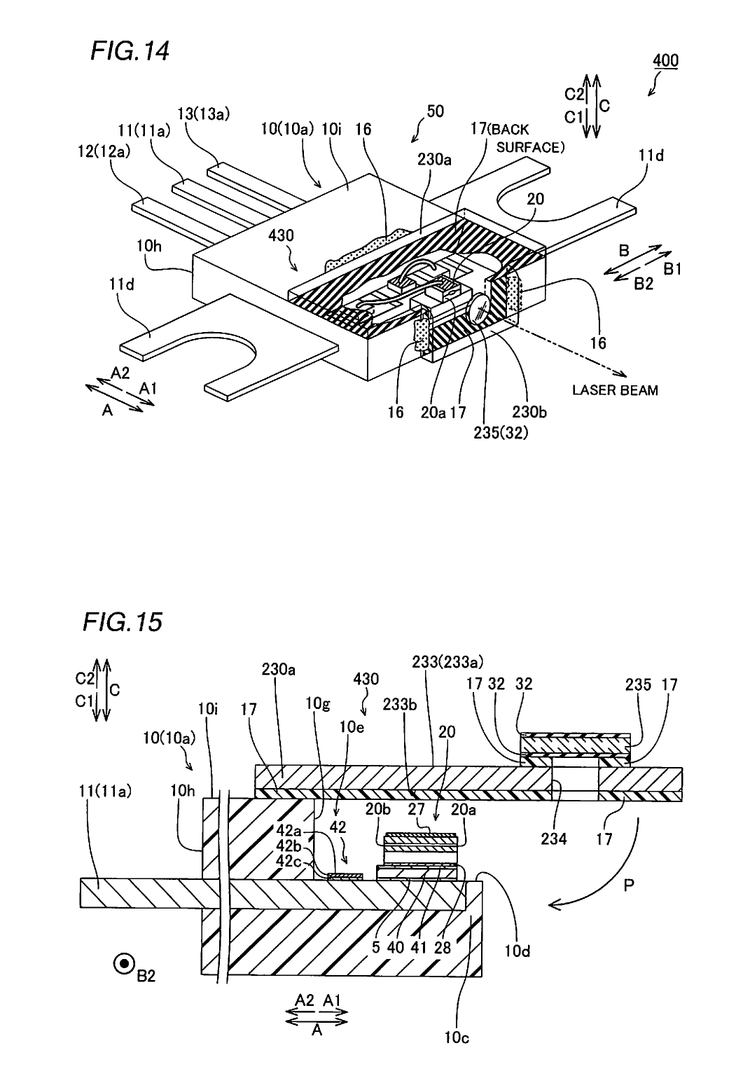

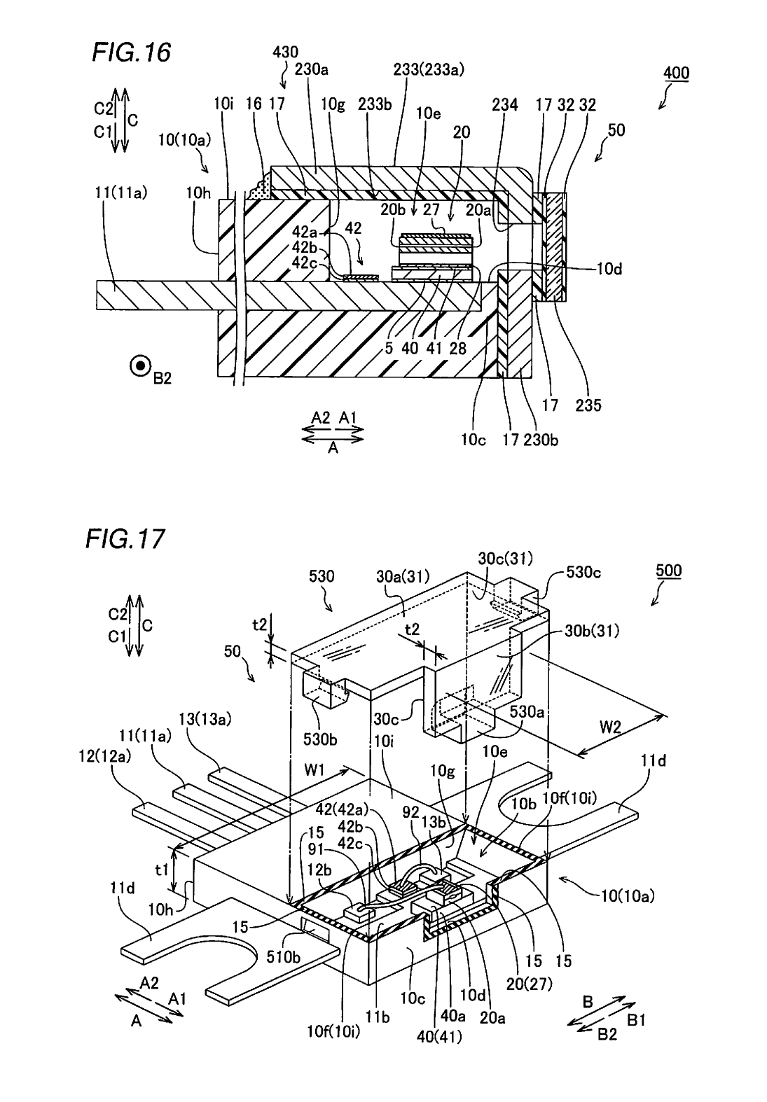

In the semiconductor laser apparatus 400, as shown in FIG. 14, the sealing member 430 and the base portion 10 are bonded to each other through the sealant 17. At this time, the sealant 17 is applied with a thickness of about 0.2 mm to not only bonded portions of the sealing member 430 and the base portion 10 but also a substantially entire region on a back surface (inner surface) of the sealing member 430. In FIG. 14, an illustration of the sealant 17 applied onto the back surface of the sealing member 430 is partially omitted, thereby illustrating the inside of a package 50. The remaining structure of the semiconductor laser apparatus 400 is similar to that of the semiconductor laser apparatus 100 according to the first embodiment.

A manufacturing process of the semiconductor laser apparatus 400 is now described. First, the sealant 17 is applied with a thickness of about 0.2 mm onto an entire back surface 233b (see FIG. 10) in a state where a sheet-like aluminum foil 233 (see FIG. 10) having a thickness of about 0.17 μm is heated to about 220° C. Thereafter, holes 234 (see FIG. 10) are formed, and the sealing member 430 having a planar shape shown in FIG. 12 is prepared after light transmission portions 235 are bonded onto the aluminum foil 233 through the sealant 17, similarly to the second embodiment. The sealant 17 applied onto the back surface 233b is also hardened by cooling, and hence a prescribed magnitude of rigidity is produced in the plate-like sealing member 430.

Thereafter, the sealing member 430 is mounted on the base portion 10 through the following step in place of a step of mounting the sealing member 230 on the base portion 10 in the manufacturing process of the semiconductor laser apparatus 200. In other words, the unbent sealing member 430 is press-bonded onto an upper surface of the base portion 10 in a state where the base portion 10 is heated to about 220° C., and the sealing member 430 is thermocompression bonded onto a front surface of a front wall portion 10c while bending the sealing member 430 along the front wall portion 10c. In the sealing member 430, the sealant 17 starts to melt by surrounding heat, and hence the aluminum foil 233 is rendered deformable.

Thereafter, the base portion 10 is cooled thereby mounting the sealing member 430 on the base portion 10. The remaining steps are similar to those of the manufacturing process of the second embodiment. The semiconductor laser apparatus 400 is formed in the aforementioned manner.

According to the fourth embodiment, the sealant 17 made of Eval is formed on the entire back surface 233b of the sealing member 430, and hence the physical strength (rigidity) is increased even when the thickness of the aluminum foil 233 is small. Thus, the material cost can be reduced. Further, unnecessary deformation in the manufacturing process can be prevented by increasing the rigidity. Further, handling in the manufacturing process becomes easier. The remaining effects are similar to those of the first embodiment.

### Fifth Embodiment

A fifth embodiment is described with reference to FIGS. 17 to 19. In a semiconductor laser apparatus 500 according to this fifth embodiment, a sealing member 530 provided with fitting pawls 530a to 530c is mounted on a base portion 10, dissimilarly to the first embodiment. In the figures, a structure similar to that of the semiconductor laser apparatus 100 according to the first embodiment is denoted by the same reference numerals.

In the semiconductor laser apparatus 500, as shown in FIG. 17, the fitting pawls 530a, 530b and 530c are integrally formed on the sealing member 530. The fitting pawl 530a convexly protrudes inward (in a direction A2) from an end of a front surface portion 30b on a C1 side, and an end portion thereof protrudes upward (in a direction C2) in a wedge shape. The fitting pawls 530b and 530c extend slightly downward (in a direction C1) from respective ends of a ceiling surface portion 30a in a direction B, and end portions thereof protrude inward (on a B1 side and a B2 side) in a wedge shape.

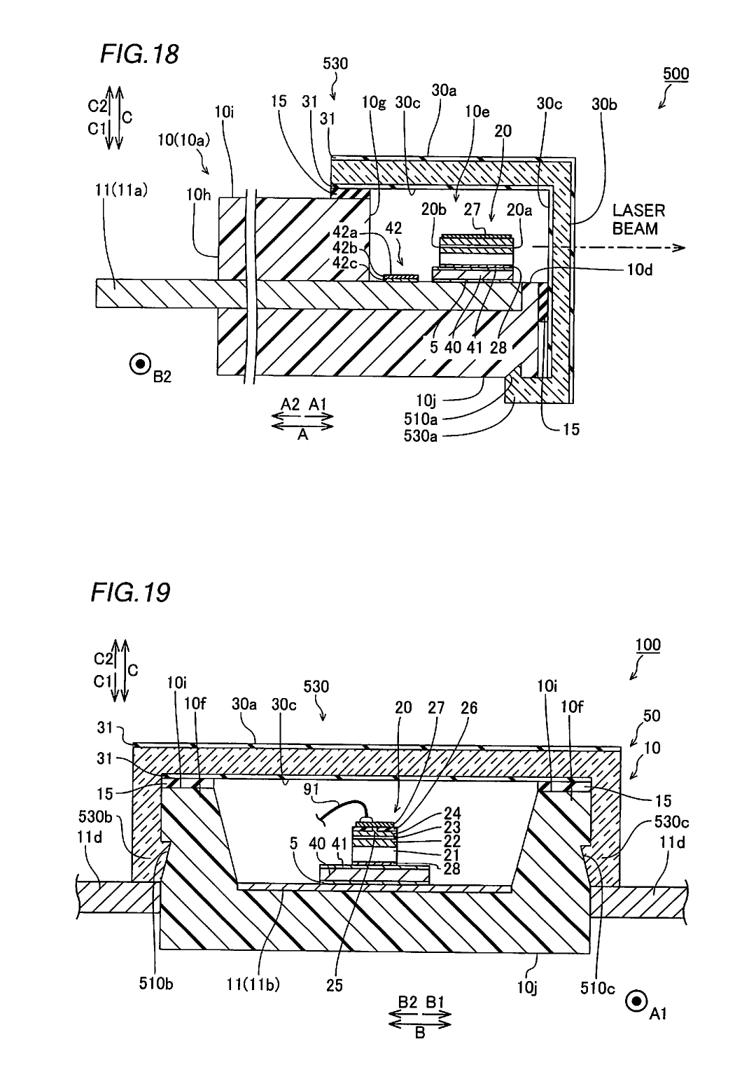

The base portion 10 is formed with fitting grooves 510a, 510b and 530c, as shown in FIGS. 17 to 19. The fitting groove 510a (see FIG. 18) is formed in a region of a lower surface 10j of the base portion 10 in the vicinity of a front wall portion 10c (on an A1 side) and recessed in the form of a substantially V-shaped groove. The fitting grooves 510b and 510c (see FIG. 19) are formed in respective outer surfaces of side wall portions 10f of a recess portion 10b and recessed in the form of a substantially V-shaped groove.

The sealing member 530 is mounted on a base body 10a through a sealant 15, similarly to the first embodiment. Further, according to the fifth embodiment, the fitting pawl 530a is fitted into the fitting groove 510a, as shown in FIG. 18, and the fitting pawls 530b and 530c are fitted into the fitting grooves 510b and 510c, respectively, as shown in FIG. 19. Thus, the sealing member 530 is fixed onto the base portion 10. At this time, the fitting pawl 530a (530b, 530c) and the fitting groove 510a (510b, 510c) are fitted into each other at a position separated from a bonded region where the base portion 10 and the sealing member 530 are bonded to each other through the sealant 15. Each of the fitting pawls 530a, 530b and 530c is examples of the “fixing means” and the “first fitting portion” in the present invention, and each of the fitting grooves 510a, 510b and 510c is examples of the “fixing means” and the “second fitting portion” in the present invention.

The remaining structure of the semiconductor laser apparatus 500 is similar to that of the semiconductor laser apparatus 100 according to the first embodiment.

A manufacturing process of the semiconductor laser apparatus 500 is substantially similar to that of the semiconductor laser apparatus 100 according to the first embodiment except that the sealing member 530 having the fitting pawls 530a, 530b and 530c is molded, the base portion 10 having the fitting grooves 510a, 510b and 510c are molded and the sealing member 530 is mounted on the base portion 10 such that the fitting pawls 530a, 530b and 530c are fitted into the fitting grooves 510a, 510b and 510c, respectively.

According to the fifth embodiment, as hereinabove described, the sealing member 530 is mounted on the base portion 10 by fitting the fitting pawls 530a, 530b and 530c into the fitting grooves 510a, 510b and 510c, respectively in addition to using the sealant 15. Thus, the sealing member 530 can be reliably fixed onto the base portion 10 by the joints (three portions) of the fitting pawls 530a, 530b and 530c and the fitting grooves 510a, 510b and 510c. Consequently, the sealing member 530 can be easily inhibited from disengaging from the base portion 10 due to a sudden vibration or impact.

The fitting pawl 530a (530b, 530c) and the fitting groove 510a (510b, 510c) are fitted into each other at the position separated from the bonded region where the base portion 10 and the sealing member 530 are bonded to each other through the sealant 15. Thus, the sealant 15 is inhibited from protruding to a fitting section of the fitting pawl 530a (530b, 530c) and the fitting groove 510a (510b, 510c) when the sealing member 530 is mounted on the base portion 10. Thus, the sealant 15 does not intervene in the fitting section of the fitting pawl 530a (530b, 530c) and the fitting groove 510a (510b, 510c), and hence the fitting pawl 530a (530b, 530c) and the fitting groove 510a (510b, 510c) can be reliably fitted into each other. Consequently, the sealing member 530 can be reliably inhibited from disengaging from the base portion 10 due to a sudden vibration or impact. The remaining effects are similar to those of the first embodiment.

### Sixth Embodiment

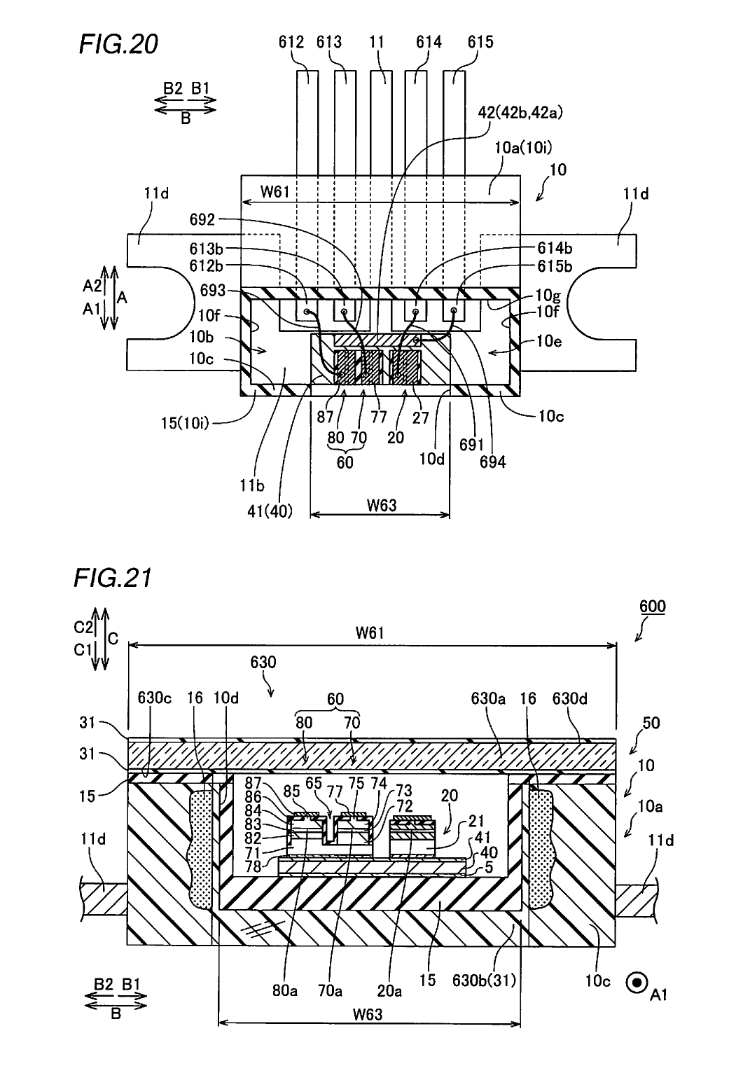

A sixth embodiment is described with reference to FIGS. 20 and 21. A three-wavelength semiconductor laser apparatus 600 according to this sixth embodiment is loaded with a plurality of semiconductor laser chips emitting laser beams having wavelengths different from each other, dissimilarly to the first embodiment. In the figures, a structure similar to that of the semiconductor laser apparatus 100 according to the first embodiment is denoted by the same reference numerals.

In the three-wavelength semiconductor laser apparatus 600 according to the sixth embodiment of the present invention, as shown in FIG. 20, a two-wavelength semiconductor laser chip 60 having a red semiconductor laser element 70 with a lasing wavelength of about 650 nm and an infrared semiconductor laser element 80 with a lasing wavelength of about 780 nm monolithically formed adjacent to a blue-violet semiconductor laser chip 20 is bonded onto a surface of a submount 40. The three-wavelength semiconductor laser apparatus 600 is an example of the “semiconductor laser apparatus” in the present invention. The two-wavelength semiconductor laser chip 60, the red semiconductor laser element 70 and the infrared semiconductor laser element 80 each are an example of the “semiconductor laser chip” in the present invention.

The aforementioned semiconductor laser chips are bonded onto prescribed regions of an upper surface of a pad electrode 41 at the front (on an A1 side), and a monitor PD 42 is bonded onto a prescribed region of the upper surface at the back (on an A2 side).

A base portion 10 is formed with a width W61 (W61>W1) by elongating a cross section of a base body 10a in a width direction (direction B), as compared with the semiconductor laser apparatus 100 of the first embodiment. Therefore, an opening 10e in an upper surface 10i is also elongated. An opening 10d provided in a substantially central portion of a front wall portion 10c has an opening length W63 (W63>W3) in the direction B. The front wall portion 10c is an example of the “one side surface” in the present invention.

In the base portion 10, lead terminals 11, 612, 613, 614 and 615 constituted by metal lead frames are so arranged on the same plane as to pass through the base body 10a in a state of being isolated from each other, as shown in FIG. 20.

Front end regions 11b and 612b to 615b of the lead terminals 11 and 612 to 615 at the front (on the A1 side) are exposed from an inner wall portion 10g of the base body 10a and arranged on a bottom surface of a recess portion 10b. The blue-violet semiconductor laser chip 20 and the two-wavelength semiconductor laser chip 60 are aligned in the direction B and fixed in a substantially central portion of the front end region 11b.

The red semiconductor laser element 70 and the infrared semiconductor laser element 80 of the two-wavelength semiconductor laser chip 60 are formed on a surface of a common n-type GaAs substrate 71 through a recess portion 65 having a prescribed groove width, as shown in FIG. 21.

Specifically, in the red semiconductor laser element 70, an n-type cladding layer 72 made of AlGaInP is formed on an upper surface of the n-type GaAs substrate 71. An active layer 73 having an MQW structure formed by alternately staking quantum well layers made of GaInP and barrier layers made of AlGaInP is formed on an upper surface of the n-type cladding layer 72. A p-type cladding layer 74 made of AlGaInP is formed on an upper surface of the active layer 73. In the infrared semiconductor laser element 80, an n-type cladding layer 82 made of AlGaAs is formed on the upper surface of the n-type GaAs substrate 71. An active layer 83 having an MQW structure formed by alternately staking quantum well layers made of AlGaAs having a lower Al composition and barrier layers made of AlGaAs having a higher Al composition is formed on an upper surface of the n-type cladding layer 82. A p-type cladding layer 84 made of AlGaAs is formed on an upper surface of the active layer 83.

A current blocking layer 86 made of SiO₂, covering an upper surface of the p-type cladding layer 74 other than a ridge 75, both side surfaces of the ridge 75, an upper surface of the p-type cladding layer 84 other than a ridge 85 and both side surfaces of the ridge 85 is formed. On upper surfaces of the ridge 75, the ridge 85 and the current blocking layer 86, p-side electrodes 77 and 87 prepared by stacking a Pt layer with a thickness of about 200 nm and an Au layer with a thickness of about 3 μm are formed.

An n-side electrode 78 prepared by stacking an AuGe layer, an Ni layer and an Au layer successively from a side closer to the n-type GaAs substrate 71 is formed on a lower surface of the n-type GaAs substrate 71. The n-side electrode 78 is provided as an n-side electrode common to the red semiconductor laser element 70 and the infrared semiconductor laser element 80. Light-emitting facets 70a and 80a of the red semiconductor laser element 70 and the infrared semiconductor laser element 80 are aligned on the same side (A1 side) as a light-emitting facet 20a. The light-emitting facets 70a and 80a are an example of the “laser emitting facet” in the present invention.

As shown in FIG. 20, a first end of a metal wire 691 is bonded to a p-side electrode 27, and a second end of the metal wire 691 is connected to the front end region 614b of the lead terminal 614. A first end of a metal wire 692 is bonded to the p-side electrode 77, and a second end of the metal wire 692 is connected to the front end region 613b of the lead terminal 613. A first end of a metal wire 693 is bonded to the p-side electrode 87, and a second end of the metal wire 693 is connected to the front end region 612b of the lead terminal 612. A first end of a metal wire 694 is bonded to a p-type region 42b of the monitor PD 42, and a second end of the metal wire 694 is connected to the front end region 615b of the lead terminal 615.

A sealing member 630 has the same width W61 as the base portion 10 by elongating cross sections of a ceiling surface portion 630a and a front surface portion 630b in the width direction (direction B), as compared with the sealing member 30 (see FIG. 1) of the first embodiment.

According to the sixth embodiment, the sealing member 630 is made of translucent thermoplastic fluorine resin. As shown in FIG. 21, gas barrier layers 31 each having a thickness of about 0.1 μm, made of SiO₂ are continuously formed on an inner surface 630c and an outer surface 630d of the sealing member 630.

The remaining structure of the three-wavelength semiconductor laser apparatus 600 is similar to that of the semiconductor laser apparatus 100 according to the first embodiment.

A manufacturing process of the sealing member 630 is now described. First, thermoplastic fluorine resin in the form of a pellet (a columnar particle having a length of about 3 to 5 mm) is heated under a temperature condition of about 170° C. and poured into a mold (not shown) having a prescribed shape. Then, the fluorine resin is hardened by removing the heat. Thus, the ceiling surface portion 630a and the front surface portion 630b (see FIG. 21) of the sealing member 630 are molded.

Thereafter, the gas barrier layers 31 made of SiO₂ are formed on respective surfaces (the inner surface 630c and the outer surface 630d) of the ceiling surface portion 630a and the front surface portion 630b of the sealing member 630 by vacuum evaporation. The sealing member 630 is formed in the aforementioned manner.

The remaining manufacturing process of the three-wavelength semiconductor laser apparatus 600 is substantially similar to that of the semiconductor laser apparatus 100 according to the first embodiment except that the blue-violet semiconductor laser chip 20 and the two-wavelength semiconductor laser chip 60 are bonded onto the submount 40 in a state of being aligned in a lateral direction (the direction B in FIG. 21) and the blue-violet semiconductor laser chip 20 and the two-wavelength semiconductor laser chip 60 are sealed by mounting the sealing member 630 on the base portion 10 through a sealant 15 after the sealing member 630 is formed of the thermoplastic fluorine resin.

In order to confirm usefulness of employing the thermoplastic fluorine resin as the sealing member 630, the following experiment was performed. First, only the blue-violet semiconductor laser chip 20 is mounted on a metal stem (base portion) having a diameter (outer diameter) of 9 mm. When the stem was sealed with a metal cap portion (with a glass window), thermoplastic fluorine resin (THV500G manufactured by Sumitomo 3M Ltd.) including tetrafluoroethylene, hexafluoropropylene and vinylidene fluoride, cut in a size of 2 mm×2 mm×0.1 mm (length×width×thickness) was put in a package. Then, an operation test was performed by emitting a laser beam adjusted to 10 mW output power by APC from the blue-violet semiconductor laser chip 20 for 250 hours under a condition of 70° C. Consequently, an operating current of a semiconductor laser apparatus did not remarkably change even after 250 hours. Further, adherent substances resulting from volatile gas generated from the thermoplastic fluorine resin were not formed on the laser emitting facet of the blue-violet semiconductor laser chip 20. As a comparative example, an operation test was performed after putting an acrylic plate cut in the same size as described above in the same package and sealing the package. In this case, the operating current started to increase after 140 hours and the laser device was broken.

The sealing member 630 was made of the thermoplastic fluorine resin (THV500G manufactured by Sumitomo 3M Ltd.) with the aforementioned thickness (0.1 mm) and arranged at a distance of 1 mm from the light-emitting facet 20a. Next, a laser beam adjusted to 10 mW output power by APC was emitted from the blue-violet semiconductor laser chip 20 to the aforementioned light transmission portion 35 for 1000 hours under a condition of 70° C., and it has been confirmed that there is no change in transmittance of the sealing member 630. When a laser beam was emitted to a light transmission portion made of PMMA (transparent acrylic resin) with a thickness of 1 mm under the same condition as a comparative example, a region to which the laser beam was emitted became opaque due to deterioration and the transmittance was rapidly reduced. From these results, it has been confirmed that the adherent substances are hardly formed on the laser emitting facet and the transmittance with respect to a blue-violet laser beam is hardly reduced by employing the thermoplastic fluorine resin as the sealing member 630.

Therefore, in the three-wavelength semiconductor laser apparatus 600 having the sealing member 630 formed of this, the blue-violet semiconductor laser chip 20 can be further inhibited from deterioration. Further, volatile gas generated from thermoplastic fluorine resin does not form adherent substances on the laser emitting facet, and hence degassing performed in the manufacturing process of the sealing member 30 according to the first embodiment is not required. Thus, the three-wavelength semiconductor laser apparatus 600 having excellent characteristics can be easily manufactured.

The effects of the three-wavelength semiconductor laser apparatus 600 are similar to those of the semiconductor laser apparatus 100 according to the first embodiment.

### Seventh Embodiment

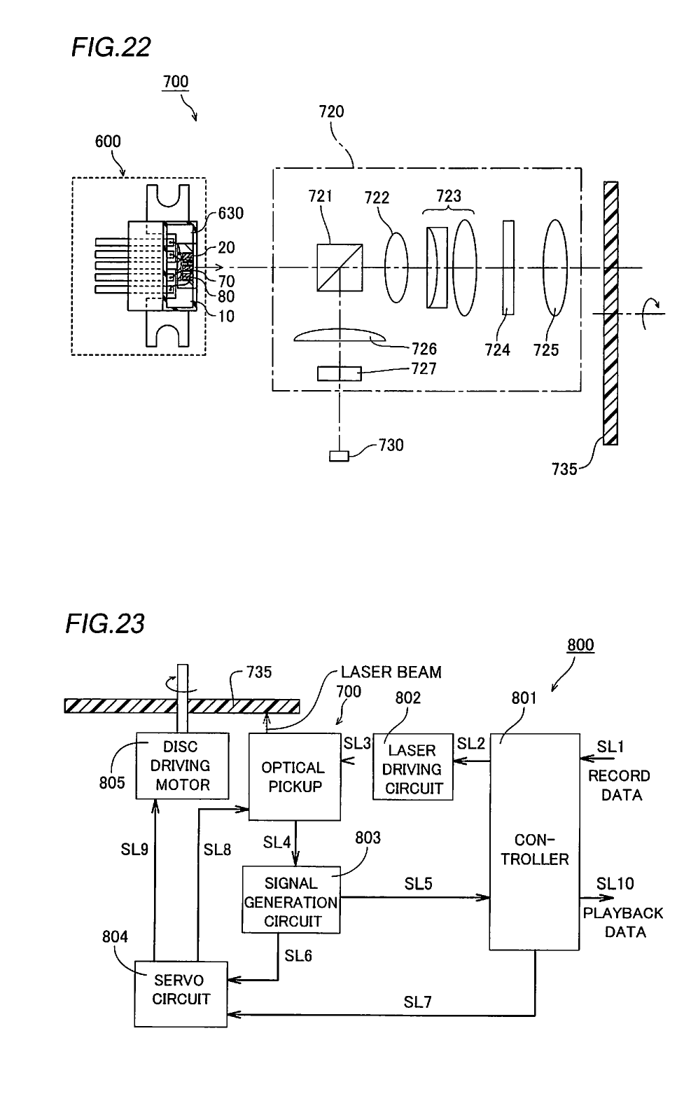

An optical pickup 700 according to a seventh embodiment of the present invention is described with reference to FIGS. 20 and 22. The optical pickup 700 is an example of the “optical apparatus” in the present invention.

The optical pickup 700 according to the seventh embodiment of the present invention comprises the three-wavelength semiconductor laser apparatus 600 (see FIG. 20), an optical system 720 adjusting a laser beam emitted from the three-wavelength semiconductor laser apparatus 600 and a light detection portion 730 receiving the laser beam, as shown in FIG. 22.

The optical system 720 has a polarizing beam splitter (PBS) 721, a collimator lens 722, a beam expander 723, a λ/4 plate 724, an objective lens 725, a cylindrical lens 726 and an optical axis correction device 727.

The PBS 721 totally transmits the laser beam emitted from the three-wavelength semiconductor laser apparatus 600, and totally reflects a laser beam fed back from an optical disc 735. The collimator lens 722 converts the laser beam emitted from the three-wavelength semiconductor laser apparatus 600 and transmitted through the PBS 721 to a parallel beam. The beam expander 723 is constituted by a concave lens, a convex lens and an actuator (not shown). The actuator has a function of correcting a wavefront state of the laser beam emitted from the three-wavelength semiconductor laser apparatus 600 by varying a distance between the concave lens and the convex lens in response to servo signals from a servo circuit described later.

The λ/4 plate 724 converts the linearly polarized laser beam, substantially converted to the parallel beam by the collimator lens 722, to a circularly polarized beam. Further, the λ/4 plate 724 converts the circularly polarized laser beam fed back from the optical disc 735 to a linearly polarized beam. In this case, a direction of polarization of the linearly polarized beam is orthogonal to a direction of polarization of the linearly polarized laser beam emitted from the three-wavelength semiconductor laser apparatus 600. Thus, the PBS 721 substantially totally reflects the laser beam fed back from the optical disc 735. The objective lens 725 converges the laser beam transmitted through the λ/4 plate 724 on a surface (recording layer) of the optical disc 735. The objective lens 725 is movable in a focus direction, a tracking direction and a tilt direction by an objective lens actuator (not shown) in response to the servo signals (a tracking servo signal, a focus servo signal and a tilt servo signal) from the servo circuit described later.

The cylindrical lens 726, the optical axis correction device 727 and the light detection portion 730 are arranged to be along an optical axis of the laser beam totally reflected by the PBS 721. The cylindrical lens 726 provides the incident laser beam with astigmatic action. The optical axis correction device 727 is formed by diffraction grating and so arranged that a spot of zeroth-order diffracted light of each of blue-violet, red and infrared laser beams transmitted through the cylindrical lens 726 coincides with each other on a detection region of the light detection portion 730 described later.

The light detection portion 730 outputs a playback signal on the basis of an intensity distribution of the received laser beam. The light detection portion 730 has a detection region of a prescribed pattern, to obtain a focus error signal, a tracking error signal and a tilt error signal along with the playback signal. The optical pickup 700 comprising the three-wavelength semiconductor laser apparatus 600 is constituted in the aforementioned manner.

In this optical pickup 700, the three-wavelength semiconductor laser apparatus 600 can independently emit blue-violet, red and infrared laser beams from the blue-violet semiconductor laser chip 20, the red semiconductor laser element 70 and the infrared semiconductor laser element 80 by independently applying voltages between the lead terminal 11 and the respective lead terminals 612 to 614. As hereinabove described, the laser beams emitted from the three-wavelength semiconductor laser apparatus 600 are adjusted by the PBS 721, the collimator lens 722, the beam expander 723, the λ/4 plate 724, the objective lens 725, the cylindrical lens 726 and the optical axis correction device 727, and thereafter irradiated on the detection region of the light detection portion 730.

When data recorded in the optical disc 735 is play backed, the laser beams are applied to the recording layer of the optical disc 735 while controlling laser power emitted from the blue-violet semiconductor laser chip 20, the red semiconductor laser element 70 and the infrared semiconductor laser element 80 to be constant and the playback signal outputted from the light detection portion 730 can be obtained. The actuator of the beam expander 723 and the objective lens actuator driving the objective lens 725 can be feedback-controlled by the focus error signal, the tracking error signal and the tilt error signal simultaneously outputted.

When data is recorded in the optical disc 735, the laser beams are applied to the optical disc 735 while controlling laser power emitted from the blue-violet semiconductor laser chip 20 and the red semiconductor laser element 70 (infrared semiconductor laser element 80) on the basis of data to be recorded. Thus, the data can be recorded in the recording layer of the optical disc 735. Similarly to the above, the actuator of the beam expander 723 and the objective lens actuator driving the objective lens 725 can be feedback-controlled by the focus error signal, the tracking error signal and the tilt error signal outputted from the light detection portion 730.

Thus, record in the optical disc 735 and playback can be performed with the optical pickup 700 comprising the three-wavelength semiconductor laser apparatus 600.

The optical pickup 700 according to the seventh embodiment comprises the three-wavelength semiconductor laser apparatus 600, and hence the reliable optical pickup 700 having the blue-violet semiconductor laser chip 20 and the two-wavelength semiconductor laser chip 60 both hard to deteriorate, capable of enduring the use for a long time can be obtained.

### Eighth Embodiment

An optical disc apparatus 800 according to an eighth embodiment of the present invention is described with reference to FIGS. 22 and 23. The optical disc apparatus 800 is an example of the “optical apparatus” in the present invention.

The optical disc apparatus 800 according to the eighth embodiment of the present invention comprises the optical pickup 700, a controller 801, a laser driving circuit 802, a signal generation circuit 803, a servo circuit 904 and a disc driving motor 805, as shown in FIG. 23.

Record data SL1 generated on the basis of data to be recorded in the optical disc 735 is inputted in the controller 801. The controller 801 outputs a signal SL2 to the laser driving circuit 802 and outputs a signal SL7 to the servo circuit 804 in response to the record data SL1 and a signal SL5 from the signal generation circuit 803 described later. The controller 801 outputs playback data SL10 on the basis of the signal SL5, as described later. The laser driving circuit 802 outputs a signal SL3 controlling laser power emitted from the three-wavelength semiconductor laser apparatus 600 in the optical pickup 700 in response to the aforementioned signal SL2. In other words, the three-wavelength semiconductor laser apparatus 600 is driven by the controller 801 and the laser driving circuit 802.

In the optical pickup 700, a laser beam controlled in response to the aforementioned signal SL3 is applied to the optical disc 735, as shown in FIG. 23. A signal SL4 is outputted from the light detection portion 730 in the optical pickup 700 to the signal generation circuit 803. The optical system 720 (the actuator of the beam expander 723 and the objective lens actuator driving the objective lens 725 shown in FIG. 22) in the optical pickup 700 is controlled by a servo signal SL8 from the servo circuit 804 described later. The signal generation circuit 803 performs amplification and arithmetic processing for the signal SL4 outputted from the optical pickup 700, to output the first output signal SL5 including a playback signal to the controller 801 and to output a second output signal SL6 performing the aforementioned feed-back control of the optical pickup 700 and rotational control, described later, of the optical disc 735 to the servo circuit 804.

The servo circuit 804 outputs the servo signal SL8 controlling the optical system 720 in the optical pickup 700 and a motor servo signal SL9 controlling the disc driving motor 805 in response to the second output signals SL6 and SL7 from the signal generation circuit 803 and the controller 801, as shown in FIG. 23. The disc driving motor 805 controls a rotational speed of the optical disc 735 in response to the motor servo signal SL9.

When data recorded in the optical disc 735 is play backed, a laser beam having a wavelength to be applied is first selected by means identifying types (CD, DVD, BD, etc.) of the optical disc 735, which is not described here. Then, the signal SL2 is so outputted from the controller 801 to the laser driving circuit 802 that an intensity of the laser beam having the wavelength to be emitted from the three-wavelength semiconductor laser apparatus 600 in the optical pickup 700 is constant. Further, the signal SL4 including a playback signal is outputted from the light detection portion 730 to the signal generation circuit 803 by functioning the three-wavelength semiconductor laser apparatus 600, the optical system 720 and the light detection portion 730 of the optical pickup 700 as described above, and the signal generation circuit 803 outputs the signal SL5 including the playback signal to the controller 801. The controller 801 processes the signal SL5, so that the playback signal recorded in the optical disc 735 is extracted and outputted as the playback data SL10. Information such as images and sound recorded in the optical disc 735 can be outputted to a monitor, a speaker and the like with this playback data SL10, for example. Feed-back control of each portion is performed on the basis of the signal SL4 from the light detection portion 730.

When data is recorded in the optical disc 735, the laser beam having the wavelength to be applied is first selected by the means identifying types of the optical disc 735, similarly to the above. Then, the signal SL2 is outputted from the controller 801 to the laser driving circuit 802 in response to the record data SL1 responsive to recorded data. Further, data is recorded in the optical disc 735 by functioning the three-wavelength semiconductor laser apparatus 600, the optical system 720 and the light detection portion 730 of the optical pickup 700 as described above, and feed-back control of each portion is performed on the basis of the signal SL4 from the light detection portion 730.

Thus, record in the optical disc 735 and playback can be performed with the optical disc apparatus 800.

In the optical disc apparatus 800 according to the eighth embodiment, the three-wavelength semiconductor laser apparatus 600 (see FIG. 22) is mounted in the optical pickup 700, and hence the reliable optical disc apparatus 800 having the blue-violet semiconductor laser chip 20 and the two-wavelength semiconductor laser chip 60 both hard to deteriorate, capable of enduring the use for a long time can be easily obtained.

### Ninth Embodiment

A structure of a projector 900 according to a ninth embodiment of the present invention is described with reference to FIGS. 22, 24 and 25. In the projector 900, individual semiconductor laser chips and elements constituting an RGB three-wavelength semiconductor laser apparatus 605 are substantially simultaneously turned on. The RGB three-wavelength semiconductor laser apparatus 605 is an example of the “semiconductor laser apparatus” in the present invention, and the projector 900 is an example of the “optical apparatus” in the present invention.

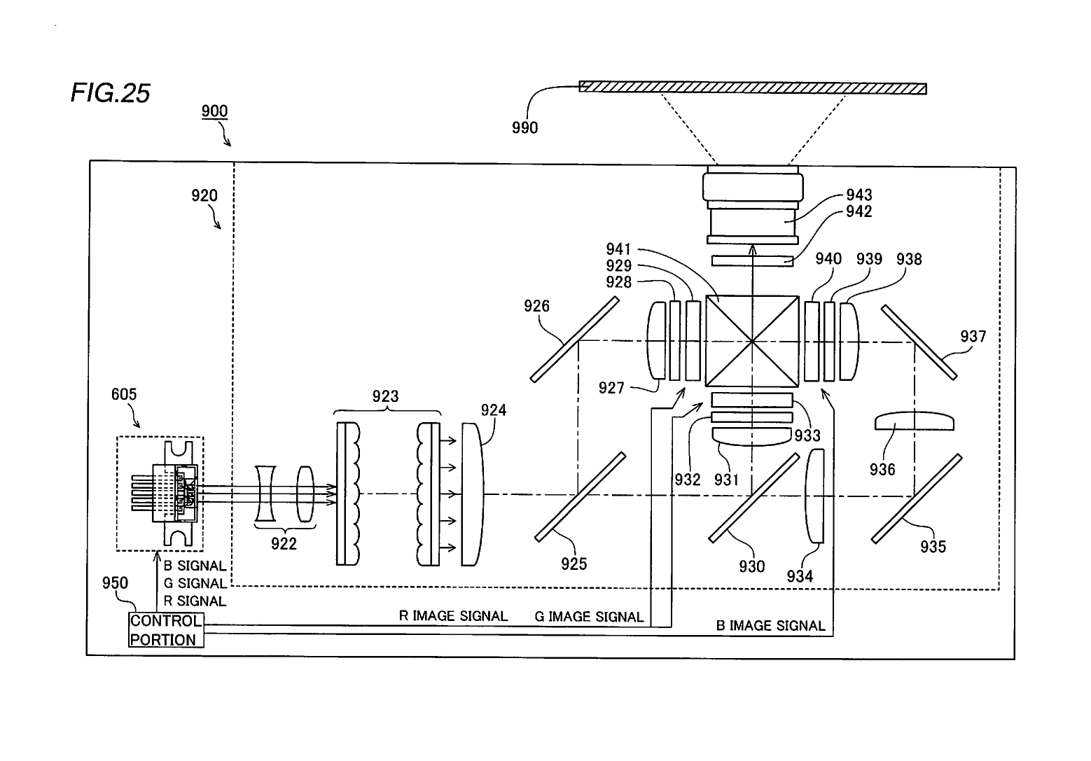

The projector 900 according to the ninth embodiment of the present invention comprises the RGB three-wavelength semiconductor laser apparatus 605, an optical system 920 constituted by a plurality of optical components and a control portion 950 controlling the RGB three-wavelength semiconductor laser apparatus 605 and the optical system 920, as shown in FIG. 25. Thus, laser beams emitted from the RGB three-wavelength semiconductor laser apparatus 605 are modulated by the optical system 920 and thereafter projected on an external screen 990 or the like.

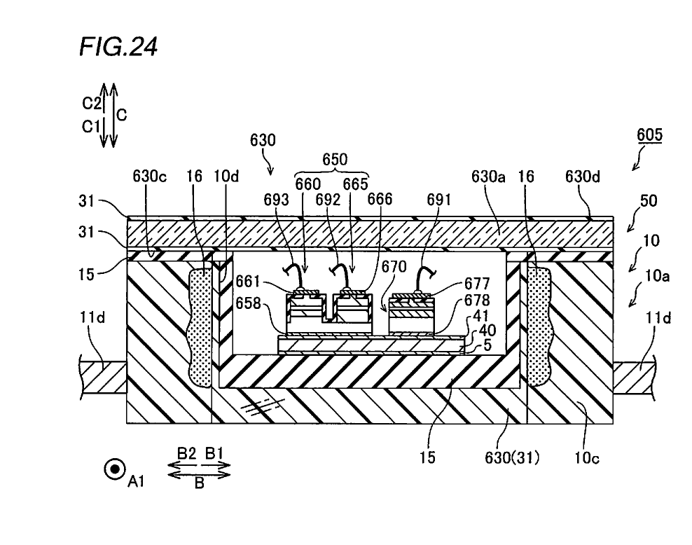

In the RGB three-wavelength semiconductor laser apparatus 605, a red semiconductor laser chip 670 with a red (R) lasing wavelength of about 655 nm is bonded to a two-wavelength semiconductor laser chip 650 having a green semiconductor laser element 660 with a green (G) lasing wavelength of about 530 nm and a blue semiconductor laser element 665 with a blue (B) lasing wavelength of about 480 nm monolithically formed, as shown in FIG. 24. The two-wavelength semiconductor laser chip 650, the green semiconductor laser element 660, the blue semiconductor laser element 665 and the red semiconductor laser chip 670 are an example of the “semiconductor laser chip” in the present invention.

The RGB three-wavelength semiconductor laser apparatus 605 comprises the red semiconductor laser chip 670 (see FIG. 24) formed on the upper surface of the n-type GaAs substrate 71 in place of the blue-violet semiconductor laser chip 20 in the three-wavelength semiconductor laser apparatus 600 shown in FIG. 21. Further, the RGB three-wavelength semiconductor laser apparatus 605 comprises the two-wavelength semiconductor laser chip 650 (see FIG. 24) having the green semiconductor laser element 660 and the blue semiconductor laser element 665 monolithically formed on the lower surface of the n-type GaN substrate 21 in place of the two-wavelength semiconductor laser chip 60 having the red semiconductor laser element 70 and the infrared semiconductor laser element 80 monolithically formed. The respective semiconductor laser chips are bonded onto the surface of the submount 40 through the pad electrode 41.

As shown in FIG. 24, the red semiconductor laser chip 670 is connected to the front end region 614b (see FIG. 20) of the lead terminal 614 through the metal wire 691 bonded to a p-side electrode 677. The blue semiconductor laser element 665 is connected to the front end region 613b (see FIG. 20) of the lead terminal 613 through the metal wire 692 bonded to a p-side electrode 666. The green semiconductor laser element 660 is connected to the front end region 612b (see FIG. 20) of the lead terminal 612 through the metal wire 693 bonded to a p-side electrode 661. The monitor PD 42 formed to be capable of receiving laser beams from light-reflecting surfaces of the respective laser chips is connected to the front end region 615b (see FIG. 20) of the lead terminal 615 through the metal wire 694 bonded to the p-type region 42b. An n-side electrode 678 of the red semiconductor laser chip 670, an n-side electrode 658 of the two-wavelength semiconductor laser chip 650 and the n-type region 42c of the monitor PD 42 are electrically connected to the lead terminal 11 through the submount 40. Thus, in the RGB three-wavelength semiconductor laser apparatus 605, cathode common connection is achieved.

The remaining structure and manufacturing process of the RGB three-wavelength semiconductor laser apparatus 605 are similar to those of the three-wavelength semiconductor laser apparatus 600.

As shown in FIG. 25, in the optical system 920, the laser beams emitted from the RGB three-wavelength semiconductor laser apparatus 605 are converted to parallel beams having prescribed beam diameters by a dispersion angle control lens 922 constituted by a convex lens and a concave lens, and thereafter introduced into a fly-eye integrator 923. The fly-eye integrator 923 is so formed that two fly-eye lenses consisting of fly-eye lens groups face each other. Thus, the fly-eye integrator 923 provides a lens function to the beams introduced from the dispersion angle control lens 922 so that quantity distributions of the beams incident upon liquid crystal panels 929, 933 and 940 are uniformized. In other words, the beams transmitted through the fly-eye integrator 923 are so adjusted that the same can be incident with spreading of an aspect ratio (16:9, for example) corresponding to the sizes of the liquid crystal panels 929, 933 and 940.

The beams transmitted through the fly-eye integrator 923 are condensed by a condenser lens 924. Among the beams transmitted through the condenser lens 924, only the red beam is reflected by a dichroic mirror 925, while the green and blue beams are transmitted through the dichroic mirror 925.

The red beam is incident upon the liquid crystal panel 929 through an incidence-side polarizing plate 928 after parallelization by a lens 927 through a mirror 926. This liquid crystal panel 929 is driven in response to a red image signal (R image signal) thereby modulating the red beam.

Only the green beam in the beams transmitted through the dichroic mirror 925 is reflected by a dichroic mirror 930, while the blue beam is transmitted through the dichroic mirror 930.

The green beam is incident upon the liquid crystal panel 933 through an incidence-side polarizing plate 932 after parallelization by a lens 931. This liquid crystal panel 933 is driven in response to a green image signal (G image signal) thereby modulating the green beam.

The blue beam transmitted through the dichroic mirror 930 is incident upon the liquid crystal panel 940 through an incidence-side polarizing plate 939 after passing through a lens 934, a mirror 935, a lens 936 and a mirror 937 and further being parallelized by a lens 938. This liquid crystal panel 940 is driven in response to a blue image signal (B image signal) thereby modulating the blue beam.

Thereafter, the red, green and blue beams modulated by the liquid crystal panels 929, 933 and 940 are synthesized by a dichroic prism 941, and thereafter introduced into a projection lens 943 through an emission-side polarizing plate 942. The projection lens 943 stores a lens group for imaging projected beams on a projected surface (screen 990) and an actuator for adjusting the zoom and the focus of a projected image by displacing a part of the lens group in an optical axis direction.

In the projector 900, stationary voltages as an R signal related to driving of the red semiconductor laser chip 670, a G signal related to driving of the green semiconductor laser element 660 and a B signal related to driving of the blue semiconductor laser element 665 are controlled by the control portion 950 to be supplied to the respective laser chips and elements of the RGB three-wavelength semiconductor laser apparatus 605. Thus, the red semiconductor laser chip 670, the green semiconductor laser element 660 and the blue semiconductor laser element 665 of the RGB three-wavelength semiconductor laser apparatus 605 are formed to be substantially simultaneously oscillated. The control portion 950 is formed to control intensity levels of the respective beams of the red semiconductor laser chip 670, the green semiconductor laser element 660 and the blue semiconductor laser element 665 of the RGB three-wavelength semiconductor laser apparatus 605, whereby hues, brightness etc. of pixels projected on the screen 990 are controlled. Thus, a desired image is projected on the screen 990 by the control portion 950.

The projector 900 loaded with the RGB three-wavelength semiconductor laser apparatus 605 is constituted in the aforementioned manner.

### Tenth Embodiment

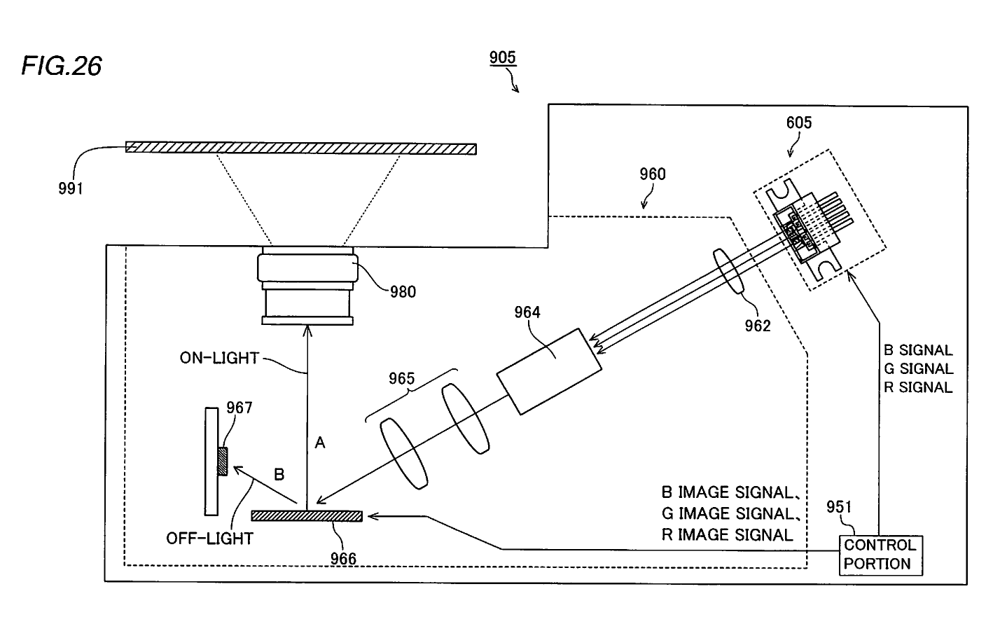

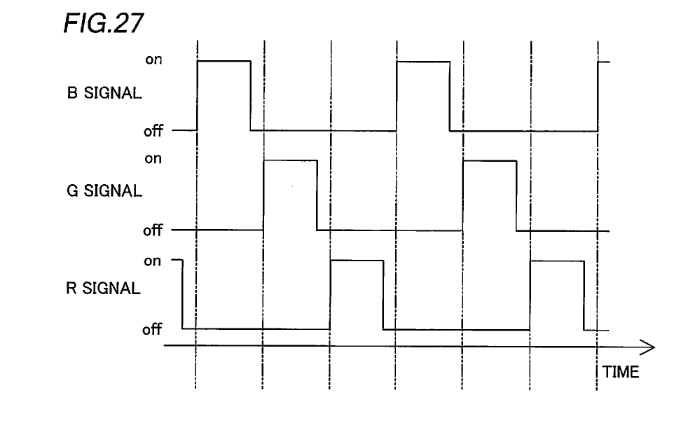

A structure of a projector 905 according to a tenth embodiment of the present invention is described with reference to FIGS. 26 and 27. In the projector 905, the individual semiconductor laser chips and elements constituting the RGB three-wavelength semiconductor laser apparatus 605 are turned on in a time-series manner.

The projector 905 according to the tenth embodiment of the present invention comprises the RGB three-wavelength semiconductor laser apparatus 605, an optical system 960 and a control portion 951 controlling the RGB three-wavelength semiconductor laser apparatus 605 and the optical system 960, as shown in FIG. 26. Thus, the laser beams from the RGB three-wavelength semiconductor laser apparatus 605 are modulated by the optical system 960 and thereafter projected on a screen 991 or the like.

In the optical system 960, the laser beams emitted from the RGB three-wavelength semiconductor laser apparatus 605 are converted to respective parallel beams by a lens 962, and thereafter introduced into a light pipe 964.

The light pipe 964 has a mirror-finished inner surface, and the laser beams travel in the light pipe 964 while the same are repetitively reflected on the inner surface of the light pipe 964. At this time, intensity distributions of the laser beams of the respective colors emitted from the light pipe 964 are uniformized due to multireflection in the light pipe 964. The laser beams emitted from the light pipe 964 are introduced into a digital micromirror device (DMD) 966 through a relay optical system 965.

The DMD 966 consists of a group of small mirrors arranged in the form of a matrix. The DMD 966 has a function of expressing (modulating) gradations of respective pixels by switching light-reflecting directions on respective pixel positions to a first direction A toward a projection lens 980 and a second direction B deviating from the projection lens 980. Among the laser beams introduced into the respective pixel positions, each beam (ON-light) reflected in the first direction A is introduced into the projection lens 980 and projected on a projected surface (screen 991). On the other hand, each beam (OFF-light) reflected in the second direction B by the DMD 966 is not introduced into the projection lens 980 but absorbed by a light absorber 967.

The projector 905 is so formed that a pulse power source is controlled by the control portion 951 to be supplied to the RGB three-wavelength semiconductor laser apparatus 605, so that the red semiconductor laser chip 670, the green semiconductor laser element 660 and the blue semiconductor laser element 665 of the RGB three-wavelength semiconductor laser apparatus 605 are divided in a time-series manner and periodically driven one by one. By the control portion 951, the DMD 966 in the optical system 960 is formed to modulate the beams in response to the gradations of the respective pixels (R, G and B) in synchronization with driven states of the red semiconductor laser chip 670, the green semiconductor laser element 660 and the blue semiconductor laser element 665.

Specifically, the R signal related to driving of the red semiconductor laser chip 670 (see FIG. 26), the G signal related to driving of the green semiconductor laser element 660 (see FIG. 26) and the B signal related to driving of the blue semiconductor laser element 665 (see FIG. 26) are supplied to the respective laser chips and elements of the RGB three-wavelength semiconductor laser apparatus 605 by the control portion 951 (see FIG. 26) in a state divided in a time-series manner not to overlap each other, as shown in FIG. 27. In synchronization with these B signal, G signal and R signal, a B image signal, a G image signal and an R image signal are outputted from the control portion 951 to the DMD 966.

Thus, the blue beam of the blue semiconductor laser element 665 is emitted on the basis of the B signal in a timing chart shown in FIG. 27, while the blue beam is modulated by the DMD 966 at this timing on the basis of the B image signal. Further, the green beam of the green semiconductor laser element 660 is emitted on the basis of the G signal outputted subsequently to the B signal, while the green beam is modulated by the DMD 966 at this timing on the basis of the G image signal. In addition, the red beam of the red semiconductor laser chip 670 is emitted on the basis of the R signal outputted subsequently to the G signal, while the red beam is modulated by the DMD 966 at this timing on the basis of the R image signal. Thereafter, the blue beam of the blue semiconductor laser element 665 is emitted on the basis of the B signal outputted subsequently to the R signal, while the blue beam is modulated by the DMD 966 at this timing on the basis of the B image signal again. The aforementioned operations are so repeated that an image resulting from laser beam application based on the B, G and R image signals is projected on the projected surface (screen 991).

The projector 905 loaded with the RGB three-wavelength semiconductor laser apparatus 605 is constituted in the aforementioned manner.

The RGB three-wavelength semiconductor laser apparatus 605 (see FIG. 24) is mounted in each of the projectors 900 and 905 according to the ninth and tenth embodiments, and hence the reliable projectors 900 and 905 having the red semiconductor laser chip 670, the green semiconductor laser element 660 and the blue semiconductor laser element 665 all hard to deteriorate, capable of enduring the use for a long time can be easily obtained.

Although the present invention has been described and illustrated in detail, it is clearly understood that the same is by way of illustration and example only and is not to be taken by way of limitation, the spirit and scope of the present invention being limited only by the terms of the appended claims.

For example, while the fluorine-based grease made of fluorine-based resin or Eval (registered trademark) made of an ethylene-polyvinyl alcohol copolymer is employed as the “sealant” in the present invention in each of the first to tenth embodiments, the present invention is not restricted to this. In the present invention, a fluorine-based organic substance such as a polymer of perfluoropolyether and tetrafluoroethylene, a polymer of hexafluoropropylene or a polymer of vinylidene fluoride or an adhesive such as a polyvinyl alcohol adhesive, an ethylene adhesive or a single component epoxy adhesive can be employed as the sealant, for example. When a single component epoxy adhesive or the like is employed, it is necessary to previously remove a volatile component sufficiently by heat.

While the light transmission portion 235 is made of the silicon resin in each of the second and fourth embodiments, in the present invention, the light transmission portion may be made of thermoplastic fluorine resin or borosilicate glass having gas barrier layers formed on the surfaces. Dielectric films such as SiO₂ or ZrO₂ in addition to Al₂O₃, or resin films having low gas permeability such as an ethylene-polyvinyl alcohol copolymer or polyvinyl alcohol may be employed as the aforementioned gas barrier layers. When each of the gas barrier layers formed on the light transmission portion is constituted by a multilayer metal oxide film of Al₂O₃, ZrO₂ or the like, this metal oxide film can also serve as an antireflection layer.

While the sealing member 230 is made of aluminum foil in each of the second and fourth embodiments, in the present invention, the sealing member may be formed by employing Cu foil, Cu alloy foil such as nickel silver, Sn foil, stainless steel foil or the like as metal foil other than aluminum foil, for example.

While the sealant 17 (Eval) is applied to the base portion 10 in a state of being heated to about 220° C. in the manufacturing process of the third embodiment, in the present invention, the base portion 10 may be heated to remove solvent after a mixture of the solvent and Eval prepared by dissolving the Eval in the solvent is applied to the base portion. When the sealant 17 is applied to the base portion 10, adhesion between the base portion 10 and the sealant (Eval) 17 can be increased by previously performing oxygen plasma treatment or UV ozone treatment on a surface of the base portion 10 and hydrophilizing the resin surface. are provided on the sealing member, and the fitting groove.

While the sealing member 530 and the base portion 10 are fitted into each other to be fixed at three portions in the fifth embodiment, in the present invention, the sealing member 530 and the base portion 10 may be fitted into each other at portions of a number other than three. While the fitting pawls (projecting portions) s (recess portions) are provided on the base portion in the fifth embodiment, in the present invention, the fitting grooves (recess portions) may be provided on the sealing member, and the fitting pawls (projecting portions) may be provided on the base portion. Further, the sealing member 530 and the base portion 10 may be more reliably fixed onto each other with the adhesives 16 employed in the first embodiment after the sealing member 530 and the base portion 10 are fitted into each other.

While the base portion is made of polyamide resin in each of the first to tenth embodiments, in the present invention, the base portion may be made of epoxy resin, polyphenylene sulfide resin or the like. Polyamide resin is suitable for a molding resin material for the base portion in that polyamide resin is smaller in generation of volatile gas than the aforementioned other resin. Further, when the semiconductor laser chip(s) is sealed with the sealing member, an adsorbent such as synthetic zeolite or silica gel shaped into a size of at least about 0.5 mm and not more than about 1.0 mm in addition to the semiconductor laser chip(s) is preferably placed in the package. Thus, a volatile gas component generated from the base portion can be adsorbed, and hence reliability of the laser chip(s) can be further improved.

What is claimed is:

1. A semiconductor laser apparatus comprising:
a semiconductor laser chip; and
a package sealing said semiconductor laser chip, wherein
said package has a concave base portion with an opening provided in an upper surface and one side surface and a sealing member covering said opening, and
said sealing member is mounted on a bonded region of said base portion through a sealant.

2. The semiconductor laser apparatus according to claim 1, wherein
said sealant is made of a material hardly generating a volatile component causing an adherent substance on a laser emitting facet of said semiconductor laser chip.

3. The semiconductor laser apparatus according to claim 2, wherein
said sealant is made of an ethylene-polyvinyl alcohol copolymer.

4. The semiconductor laser apparatus according to claim 2, wherein
said sealant is made of fluorine-based resin.

5. The semiconductor laser apparatus according to claim 4, wherein
said fluorine-based resin is fluorine-based grease.

6. The semiconductor laser apparatus according to claim 1, wherein
said sealing member has a first portion covering said upper surface of said base portion and a second portion covering said one side surface of said base portion, and
said first portion and said second portion of said sealing member are integrally formed.

7. The semiconductor laser apparatus according to claim 6, wherein
said sealing member has translucence.

8. The semiconductor laser apparatus according to claim 6, wherein
said package further includes a window member through which light emitted from said semiconductor laser chip penetrates to an outside thereof,
said sealing member further has a hole penetrating through said second portion, and
said window member is mounted on said second portion through said sealant to seal said hole of said second portion.

9. The semiconductor laser apparatus according to claim 8, wherein
said window member is bonded onto a surface of said second portion opposite to a surface mounted on said base portion through said sealant.

10. The semiconductor laser apparatus according to claim 1, wherein
said sealant is provided with no clearance all over said bonded region.

11. The semiconductor laser apparatus according to claim 1, wherein
said sealing member is fixed onto said base portion with fixing means.

12. The semiconductor laser apparatus according to claim 11, wherein
said fixing means includes an adhesive, and said adhesive is provided outside said bonded region.

13. The semiconductor laser apparatus according to claim 11, wherein
said fixing means includes a first fitting portion formed on said sealing member and a second fitting portion formed on said base portion, and
said sealing member is fixed onto said base portion by fitting said first fitting portion of said sealing member into said second fitting portion of said base portion.

14. The semiconductor laser apparatus according to claim 13, wherein
said first fitting portion and said second fitting portion are fitted into each other at a position separated from said bonded region.

15. The semiconductor laser apparatus according to claim 1, wherein
said base portion and said sealing member are made of resin.

16. The semiconductor laser apparatus according to claim 1, wherein
said sealing member is made of any of metal foil, silicon resin having a gas barrier layer formed on a surface and thermoplastic fluorine resin having a gas barrier layer formed on a surface.

17. The semiconductor laser apparatus according to claim 16, wherein
said sealing member is made of Al metal foil,
said sealant is made of an ethylene-polyvinyl alcohol copolymer, and
said sealant extends to a surface of said sealing member bonded to said base portion other than said bonded region.

18. The semiconductor laser apparatus according to claim 16, wherein
said gas barrier layer is formed on a surface of said sealing member bonded to said base portion, and
said gas barrier layer is in contact with said sealant.

19. The semiconductor laser apparatus according to claim 1, wherein
said semiconductor laser chip is a nitride-based semiconductor laser chip.

20. An optical apparatus comprising:
a semiconductor laser apparatus including a semiconductor laser chip and a package sealing said semiconductor laser chip; and
an optical system controlling a beam emitted from said semiconductor laser apparatus, wherein
said package has a concave base portion with an opening provided in an upper surface and one side surface and a sealing member covering said opening, and
said sealing member is mounted on a bonded region of said base portion through a sealant.
